(19) United States
(12) Patent Application Publication
(10) Pub. No.: US 2025/0380507 A1
(43) Pub. Date: Dec. 11, 2025

(54) SEMICONDUCTOR DEVICE AND METHOD THEREOF

(71) Applicants: TAIWAN SEMICONDUCTOR MANUFACTURING COMPANY, LTD., Hsinchu (TW); National Yang Ming Chiao Tung University, Hsinchu City (TW)

(72) Inventors: Po-Tsang HUANG, Hsinchu City (TW); Yuan-Yu HUANG, Keelung City (TW); Pin SU, Hsinchu County (TW); Chun-Jung SU, Hsinchu City (TW)

(73) Assignees: TAIWAN SEMICONDUCTOR MANUFACTURING COMPANY, LTD., Hsinchu (TW); National Yang Ming Chiao Tung University, Hsinchu City (TW)

(21) Appl. No.: 18/736,127

(22) Filed: Jun. 6, 2024

(51) Int. Cl. H01L 27/118; G11C 11/22

(52) U.S. Cl. CPC H10D 84/907; G11C 11/223; G11C 11/2275; H10D 84/938; H10D 84/953

(57) ABSTRACT

A method includes forming a first semiconductor layer and a second semiconductor layer vertically above the first semiconductor layer over a substrate; forming a first ferroelectric layer and a second ferroelectric layer wrapping around the first semiconductor layer and the second semiconductor layer, respectively; forming a first gate structure and a second gate structure over the first ferroelectric layer and the second ferroelectric layer, respectively, wherein the first gate structure is in contact with the second gate structure; and forming a conductive feature electrically connecting a drain region of the first semiconductor layer with a drain region of the second semiconductor layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a semiconductor device in accordance with some embodiments of the present disclosure.

FIG. 1B is a cross-sectional view of a semiconductor device in accordance with some embodiments of the present disclosure.

FIG. 1C is a circuit diagram of a semiconductor device in accordance with some embodiments of the present disclosure.

FIG. 1D is a simulation result of a semiconductor device at different polarization states in accordance with some embodiments of the present disclosure.

FIGS. 2A to 13 illustrate a method in various stages of forming a semiconductor device in accordance with some embodiments of the present disclosure.

FIG. 14 is a circuit diagram of a semiconductor device in accordance with some embodiments of the present disclosure.

FIG. 15A is a circuit diagram of a semiconductor device in accordance with some embodiments of the present disclosure.

FIGS. 15B and 15C are simulation results of a semiconductor device in accordance with some embodiments of the present disclosure.

FIG. 16A is a circuit diagram of a semiconductor device in accordance with some embodiments of the present disclosure.

FIGS. 16B and 16C are simulation results of a semiconductor device in accordance with some embodiments of the present disclosure.

FIG. 17 is a circuit diagram of a semiconductor device in accordance with some embodiments of the present disclosure.

FIGS. 18A, 19A, 20A, and 21A are circuit diagrams of a semiconductor device at different polarization states in accordance with some embodiments of the present disclosure.

FIGS. 18B, 19B, 20B, and 21B are simulation results a semiconductor device at different polarization states in accordance with some embodiments of the present disclosure.

FIGS. 22A, 22B, 22C, and 22D are a circuit diagram, an equivalent circuit, a true table, and a simulation result of a semiconductor device, respectively, in accordance with some embodiments of the present disclosure.

FIGS. 23A, 23B, 23C, and 23D are a circuit diagram, an equivalent circuit, a true table, and a simulation result of a semiconductor device, respectively, in accordance with some embodiments of the present disclosure.

FIGS. 24A, 24B, 24C, and 24D are a circuit diagram, an equivalent circuit, a true table, and a simulation result of a semiconductor device, respectively, in accordance with some embodiments of the present disclosure.

FIG. 25 is a perspective view of a semiconductor device in accordance with some embodiments of the present disclosure.

FIGS. 26 to 31 illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As the semiconductor industry further progresses into technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other.

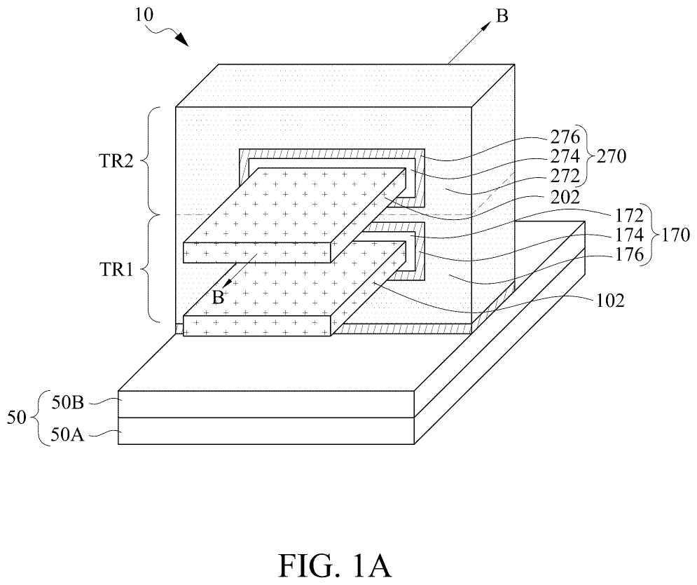

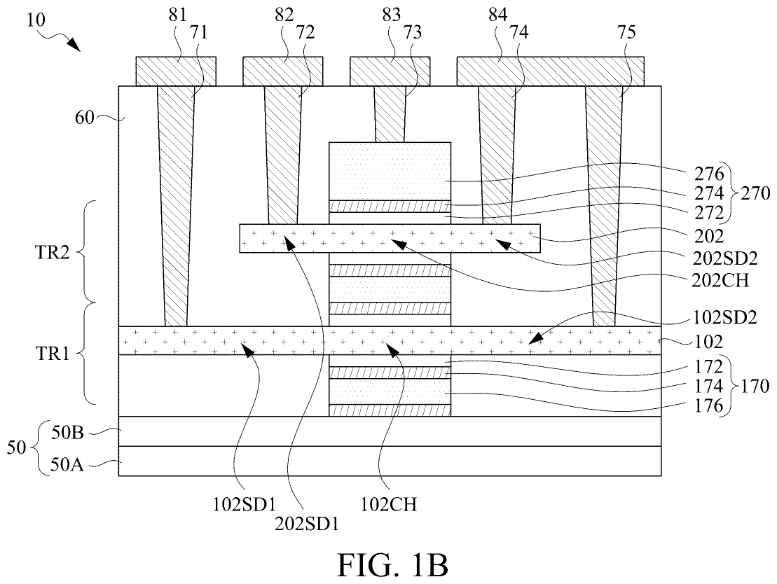

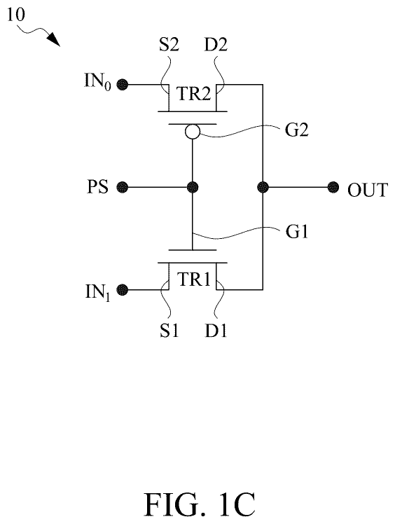

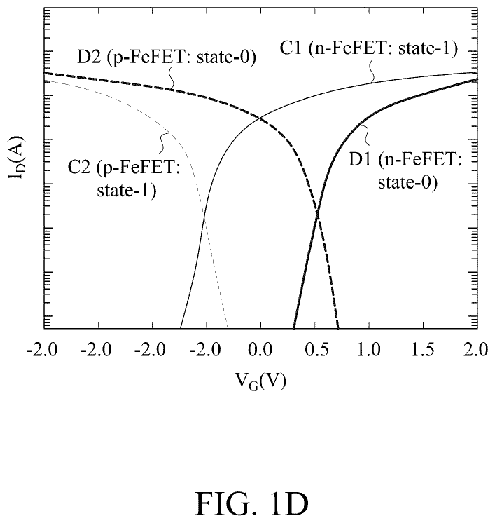

FIG. 1A is a perspective view of a semiconductor device in accordance with some embodiments of the present disclosure. FIG. 1B is a cross-sectional view of a semiconductor device in accordance with some embodiments of the present disclosure. FIG. 1C is a circuit diagram of a semiconductor device in accordance with some embodiments of the present disclosure. In greater detail, FIG. 1A illustrates a perspective view of a semiconductor device 10, FIG. 1B is a cross-sectional view along line B-B of FIG. 1A, and FIG. 1C is a circuit diagram of the semiconductor device 10. It is noted that some elements as described in FIG. 1B are not illustrated in FIG. 1A for brevity.

A complementary FET (CFET) 10 is provided, and its manufacturing method will be disclosed in the following discussion. More specifically, the CFET 10 is a complementary ferroelectric FET (CFeFET), which includes ferroelectric transistors stacked on above another, which will be discussed in the following content.

Reference is made to FIGS. 1A and 1B, in the CFET 10, a first transistor TR1 is disposed over a substrate 50, and a second transistor TR2 is disposed vertically above the first transistor TR1. In some embodiments, the first transistor TR1 and the second transistor TR2 each may be field effect transistor (FET) and may both include gate-all-around (GAA) configuration, and thus the first transistor TR1 and the second transistor TR2 can also be referred to as GAA FETs.

With respect to the first transistor TR1, the first transistor TR1 includes a first semiconductor layer 102, a first metal gate structure 170 wrapping around a channel region 102CH of the first semiconductor layer 102, in which the first semiconductor layer 102 also include source/drain regions 102SD1 and 102SD2 on opposite sides of the channel region 102CH. Similarly, the second transistor TR2 includes a second semiconductor layer 202, a second metal gate structure 270 wrapping around a channel region 202CH of the second semiconductor layer 202, in which the second semiconductor layer 202 also include source/drain regions 202SD1 and 202SD2 on opposite sides of the channel region 202CH. The first metal gate structure 170 may include an interfacial layer 172, a ferroelectric layer 174, and a gate electrode 176. Similarly, the second metal gate structure 270 may include an interfacial layer 272, a ferroelectric layer 274, and a gate electrode 276. In some embodiments, the first transistor TR1 has a first conductivity type (e.g., n-type) and the second transistor TR2 has a second conductivity type (e.g., p-type) different from the first conductivity type. In other embodiments, the first transistor TR1 has the second conductivity type (e.g., p-type) and the second transistor TR2 has the first conductivity type (e.g., n-type).

In some embodiments, the substrate 50 may include a semiconductor layer 50A and an insulating layer 50B over the semiconductor layer 50A. In other embodiments, the insulating layer 50B may be omitted. In such embodiments, the first transistor TR1 may be directly disposed on the semiconductor layer 50A. The semiconductor layer 50A generally include crystalline semiconductor material, such as silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates. The insulating layer 50B may include may be a buried oxide (BOX) layer formed by a process such as separation by implanted oxygen (SIMOX), and/or other suitable processes. In some embodiments, the insulating layer 50B is a silicon oxide (SiO₂) layer.

The first semiconductor layer 102 and the second semiconductor layer 202 may include silicon or other suitable semiconductor material. In some embodiments, the source/drain regions 102SD1 and 102SD2 of the first semiconductor layer 102 and the source/drain regions 202SD1 and 202SD2 of the second semiconductor layer 202 include different types of dopants, and therefore include different conductivity types. For example, if the first transistor TR1 is an n-type device and the second transistor TR2 is a p-type device, the source/drain regions 102SD1 and 102SD2 may include n-type dopants while the source/drain regions 202SD may include p-type dopants. On the other hand, if the first transistor TR1 is a p-type device and the second transistor TR2 is an n-type device, the source/drain regions 102SD1 and 102SD2 may include p-type dopants while the source/drain regions 202SD1 and 202SD2 may include n-type dopants. P-type dopants may include boron (B), gallium (Ga), indium (In), aluminium (Al), or the like. N-type dopants may include phosphorus (P), arsenic (As), or antimony (Sb), or the like. In some embodiments, the channel region 102CH of the first semiconductor layer 102 and the channel region 202CH of the second semiconductor layer 202 may be intrinsic (e.g., un-doped or negligibly doped).

The interfacial layer 172 of the first metal gate structure 170 and the interfacial layer 272 of the second metal gate structure 270 may be made of oxide, such as aluminum oxide (Al₂O₃), silicon oxide (SiO₂), or the like. In other embodiments, each of the interfacial layers 172 and 172 may include an oxide layer (e.g., silicon oxide) and a high-k dielectric layer over the oxide layer. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The ferroelectric layer 174 of the first metal gate structure 170 and the ferroelectric layer 274 of the second metal gate structure 270 may include materials that are capable of switching between two different polarization directions by applying an appropriate voltage differential across each of the ferroelectric layers 174 and 274. For example, the ferroelectric layers 174 and 274 include a high-k dielectric material, such as a hafnium (Hf) based dielectric materials or the like. In some embodiments, the ferroelectric layers 174 and 274 include hafnium oxide (HfO₂), hafnium zirconium oxide (HZO), silicon-doped hafnium oxide, or the like.

In some embodiments, the ferroelectric layers 174 and 274 may include barium titanium oxide (BaTiO₃), lead titanium oxide (PbTiO₃), lead zirconium oxide (PbZrO₃), lithium niobium oxide (LiNbO₃), sodium niobium oxide (NaNbO₃), potassium niobium oxide (KNbO₃), potassium tantalum oxide (KTaO₃), bismuth scandium oxide (BiScO₃), bismuth iron oxide (BiFeO₃), hafnium erbium oxide (Hf₁₋ₓErₓO), hafnium lanthanum oxide (Hf₁₋ₓLaₓO), hafnium yttrium oxide (Hf₁₋ₓYₓO), hafnium gadolinium oxide (Hf₁₋ₓGdₓO), hafnium aluminum oxide (Hf1−xAlxO), hafnium zirconium oxide (Hf₁₋ₓZrₓO, HZO), hafnium titanium oxide (Hf₁₋ₓTiₓO), hafnium tantalum oxide (Hf₁₋ₓTaₓO), or the like. In other embodiments, the ferroelectric layers 174 and 274 include HfZrO, HfAlO, HfLaO, HfCeO, HfO, HfGdO, HfSiO or a combination thereof.

In some embodiments, each of the ferroelectric layers 174 and 274 has a thickness of about 2 nm to about 10 nm, while other thickness ranges may be applicable. In some embodiments, each of the ferroelectric layers 174 and 274 is formed in a fully crystalline state. In alternative embodiments, each of the ferroelectric layers 174 and 274 has partially crystalline state; that is, each of the ferroelectric layers 174 and 274 is formed in a mixed crystalline-amorphous state and having some degree of structural order. In some embodiments, each of the ferroelectric layers 174 and 274 is a single layer. In alternative embodiments, each of the ferroelectric layers 174 and 274 has a multi-layer structure.

The gate electrode 176 of the first metal gate structure 170 and the gate electrode 276 of the second metal gate structure 270 each may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

The gate electrodes 176 and 276 are connected with each other. In some embodiments, the gate electrodes 176 and 276 are made of a same material, and may be formed through a same deposition process. That is, the first transistor TR1 and the second transistor TR2 may share a common gate electrode (e.g., the combination of gate electrodes 176 and 276). Accordingly, the first metal gate structure 170 of the first transistor TR1 is electrically connected with the second metal gate structure 270 of the second transistor TR2.

The CFET 10 further includes a dielectric layer 60 covering the first transistor TR1 and the second transistor TR2. In some embodiments, the dielectric layer 60 may include oxide, such as silicon oxide (SiO₂), aluminum oxide (Al₂O₃). In other embodiments, the dielectric layer 60 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials.

The CFET 10 further includes conductive vias 71, 72, 73, 74, and 75 in the dielectric layer 60. In greater detail, the conductive via 71 is in contact with the source/drain region 102SD1 of the first transistor TR1. The conductive via 72 is in contact with the source/drain region 202SD1 of the second transistor TR2. The conductive via 73 is in contact with the second metal gate structure 270 of the second transistor TR2. The conductive via 74 is in contact with the source/drain region 202SD2 of the second transistor TR2. The conductive via 75 is in contact with the source/drain region 102SD2 of the first transistor TR1. The conductive vias 71, 72, 73, 74, and 75 may include a conductive material, such tungsten (W), copper (Cu), aluminum (Al), ruthenium (Ru), cobalt (Co), molybdenum (Mo), nickel (Ni), or other suitable conductive material.

The CFET 10 further includes conductive pads 81, 82, 83, and 84 over the dielectric layer 60. In greater detail, the conductive pad 81 is in contact with the conductive via 71 and is electrically connected with the source/drain region 102SD1 of the first transistor TR1. The conductive pad 82 is in contact with the conductive via 72 and is electrically connected with the source/drain region 202SD1 of the second transistor TR2. The conductive pad 83 is in contact with the conductive via 73 and is electrically connected with both the second metal gate structure 270 of the second transistor TR2 and the first metal gate structure 170 of the first transistor TR1. The conductive pad 84 is in contact with the conductive vias 74 and 75, and is electrically connected with both the source/drain region 202SD2 of the second transistor TR2 and the source/drain region 102SD2 of the first transistor TR1. In some embodiments, the conductive pads 81, 82, 83, and 84 are spaced apart from each other. The conductive pads 81, 82, 83, and 84 may include a conductive material, such tungsten (W), copper (Cu), aluminum (Al), ruthenium (Ru), cobalt (Co), molybdenum (Mo), nickel (Ni), or other suitable conductive material.

Reference is made to FIG. 1C, in which FIG. 1C is a circuit diagram of the CFET 10 as described above with respect to FIGS. 1A and 1B. The source S1 of the first transistor TR1 is electrically coupled with an input terminal IN₁, and the source S2 of the second transistor TR2 is electrically coupled with an input terminal IN₀, respectively. The drain D1 of the first transistor TR1 and the drain D2 of the second transistor TR2 are electrically coupled with each other, and are electrically coupled with an output terminal OUT. The gate G1 of the first transistor TR1 and the gate G2 of the second transistor TR2 are electrically coupled with each other, and are electrically coupled with a polarization state terminal PS.

With respect to FIGS. 1A to 1C, the gate G1, the source S1, and the drain D1 of the first transistor TR1 may be the first metal gate structure 170, the source/drain region 101SD1, and the source/drain region 101SD2, respectively. Similarly, the gate G2, the source S2, and the drain D2 of the second transistor TR2 may be the second metal gate structure 270, the source/drain region 201SD1, and the source/drain region 201SD2, respectively. The conductive pads 81, 82, 83, and 84 of FIG. 1B may serve as the input terminal IN₁, the input terminal IN₀, the polarization state terminal PS, and the output terminal OUT of FIG. 1C, respectively.

FIG. 1D is a simulation result of a semiconductor device at different polarization states in accordance with some embodiments of the present disclosure. In greater detail, FIG. 1D illustrates different drain current (I_{D}) versus gate voltage (V_{G}) curves of the first transistor TR1 and the second transistor TR2 of FIG. 1C under different polarization states. As mentioned above, the first transistor TR1 and the second transistor TR2 both are ferroelectric transistors, and thus the first transistor TR1 and the second transistor TR2 may be polarized to have different resistivity states. In greater detail, the ferroelectric layers 174 and 274 may be polarized to have different polarization states, and therefore different resistivity states.

In a first polarization state (state-1), a positive write voltage may be applied to the polarization state terminal PS, and the first transistor TR1 and the second transistor TR2 are polarized positively simultaneously. After first transistor TR1 and the second transistor TR2 are polarized, the first transistor TR1 (e.g., n-type FeFET) may operate in depletion mode, as shown by curve C1. Conversely, the second transistor TR2 (e.g., p-type FeFET) may operate in enhancement mode, as indicated by curve C2. In some embodiments, during applying the write voltage, the input terminals IN₁ and IN₀ may be biased at ground voltage (e.g., 0V).

On other hand, in a second polarization state (state-0), when a negative write voltage is applied to the polarization state terminal PS, the first transistor TR1 and the second transistor TR2 are polarized negatively simultaneously. After first transistor TR1 and the second transistor TR2 are polarized, the first transistor TR1 (e.g., n-type FeFET) may operate in enhancement mode, as shown by curve D1. Conversely, the second transistor TR2 (e.g., p-type FeFET) may operate in depletion mode, as indicated by curve D2. In some embodiments, during applying the write voltage, the input terminals IN₁ and IN₀ may be biased at ground voltage (e.g., 0V).

Here, when a transistor is operated in a “depletion-mode”, the transistor may include a low-resistance when the gate voltage V_{G} is zero (V_{G}=0), as shown by curves C1 and D2. That is, the transistor may be at an ON-state when gate voltage V_{G} is zero (V_{G}=0). In contrast, when a transistor is operated in an “enhancement-mode”, the transistor may include a high-resistance when gate voltage V_{G} is zero (V_{G}=0), as shown by curves C2 and D1. That is, the transistor may be at an OFF-state when the gate voltage V_{G} is zero (V_{G}=0). In some embodiments, the ON/OFF ratio of the complementary paths is larger than 10⁶, which provides sufficient capability for various applications, and will be discussed in more detail later. Alternatively, the ratio of the drain current of the ON-state transistor to the drain current of the OFF-state transistor is larger than 10⁶.

With such configuration, the CFET 10 as described above may include various applications, which will be discussed in more detail later. In some embodiments, by appropriately adjusting the metal work functions of the n-type and p-type ferroelectric transistors, their high-Vth and low-Vth can be symmetrically aligned at VG=0V.

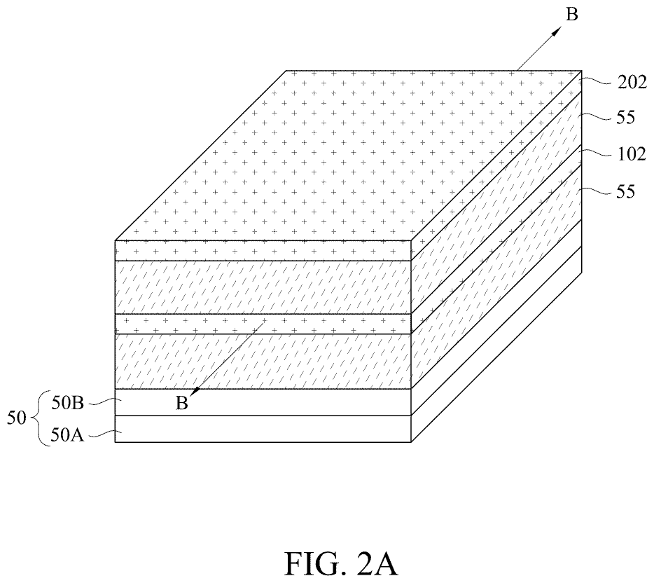

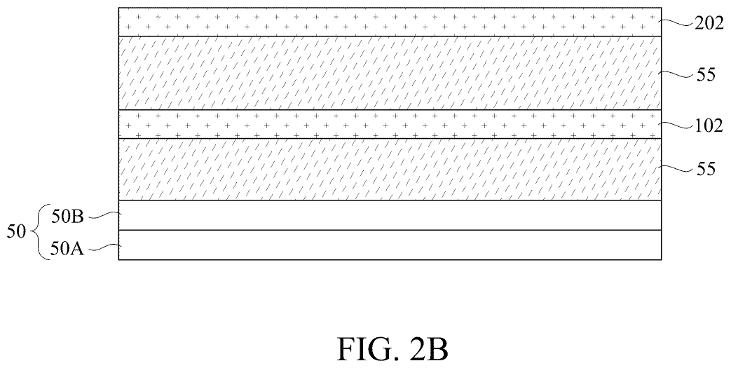

FIGS. 2A to 13 illustrate a method in various stages of forming a semiconductor device in accordance with some embodiments of the present disclosure. In greater detail, FIGS. 2A to 13 illustrate a method for forming the CFET 10 of FIGS. 1A and 1B. Although FIGS. 2A to 13 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 13 have been discussed above with respect to FIGS. 1A and 2B, such elements are labeled the same, and relevant details will not be repeated for brevity.

Reference is made to FIGS. 2A and 2B, in which FIG. 2A is a perspective view of a semiconductor device, FIG. 2B is a cross-sectional view along line B-B of FIG. 2A. Shown there is an initial structure. A stack of a sacrificial layer 55, a first semiconductor layer 102, a sacrificial layer 55, and a second semiconductor layer 202 is formed over a substrate 50.

In some embodiments, the semiconductor layers 102 and 202 may be made of pure silicon layers that are free of germanium. In some embodiments, the semiconductor layers 102 and 202 may also be substantially pure silicon layers, for example, with a germanium percentage lower than about 1 percent. The sacrificial layers 55 may be made of silicon germanium. For example, the germanium percentage (atomic percentage concentration) of the sacrificial layers 55 may be in a range from about 20 percent and about 60 percent. In some embodiments, the semiconductor layers 102 and 202, and the sacrificial layers 55 may be deposited using suitable deposition process, such as selective epitaxial growth (SEG), chemical vapor deposition (CVD), molecular beam epitaxy (MBE), or other suitable process(es). In some embodiments, the sacrificial layers 55 may be removed during a replacement gate (RPG) process. The sacrificial layers 55 may also be referred to as sacrificial semiconductor layers.

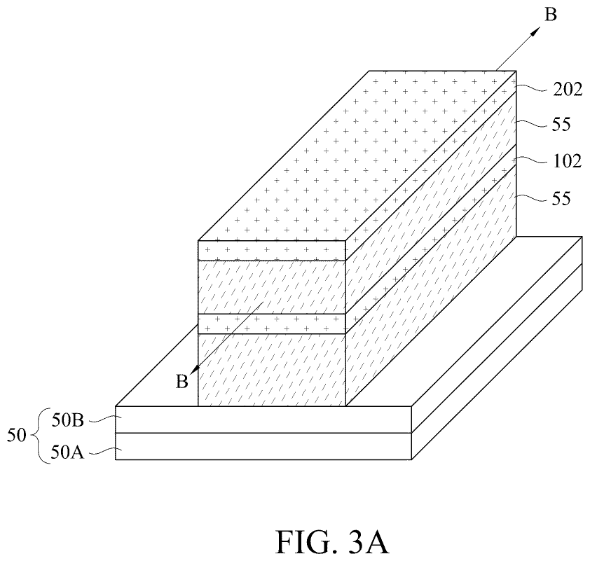

Reference is made to FIGS. 3A and 3B, in which FIG. 3A is a perspective view of a semiconductor device, FIG. 3B is a cross-sectional view along line B-B of FIG. 3A. The stack of the sacrificial layer 55, the first semiconductor layer 102, the sacrificial layer 55, and the second semiconductor layer 202 is patterned to form a fin structure protruding from the top surface the substrate 50. In some embodiments, a patterned mask (not shown) may be formed over the stack, an etching process may be performed by using the patterned mask as etch mask to remove unwanted portions of the stack, and the remaining portion of the stack is referred to as the fin structure. The patterned mask is then removed once the fin structure is formed.

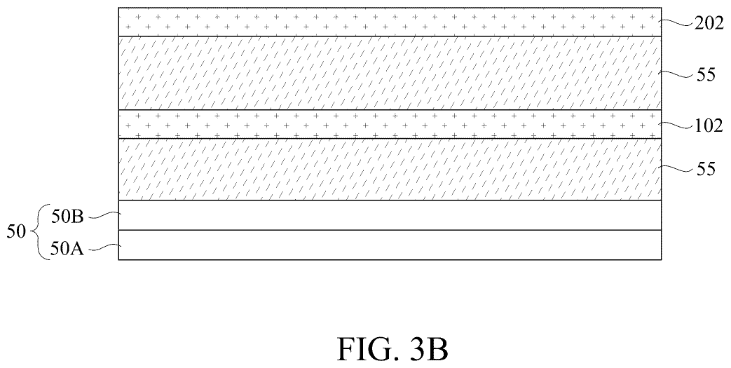

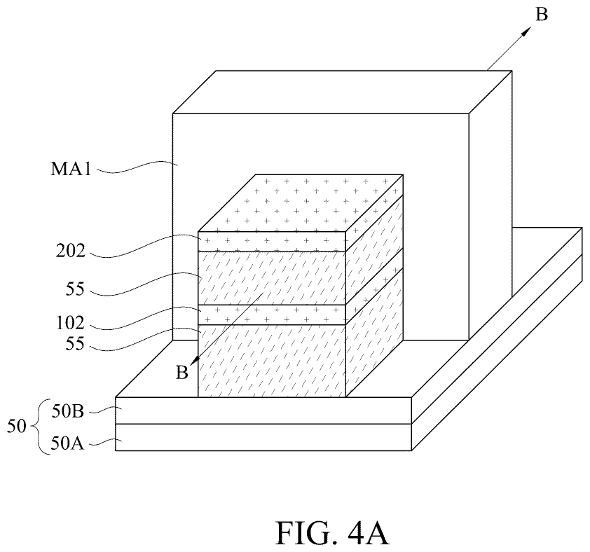

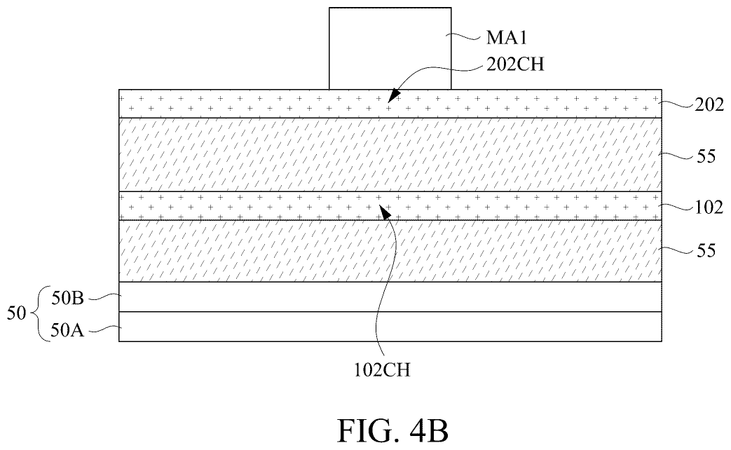

Reference is made to FIGS. 4A and 4B, in which FIG. 4A is a perspective view of a semiconductor device, FIG. 4B is a cross-sectional view along line B-B of FIG. 4A. A patterned mask MA is formed over the fin structure of the sacrificial layer 55, the first semiconductor layer 102, the sacrificial layer 55, and the second semiconductor layer 202. In some embodiments, the patterned mask MA is formed covering channel region 102CH of the first semiconductor layer 102 and the channel region 202CH of the second semiconductor layer 202. In some embodiments, the patterned mask MA may be photoresist or hard mask.

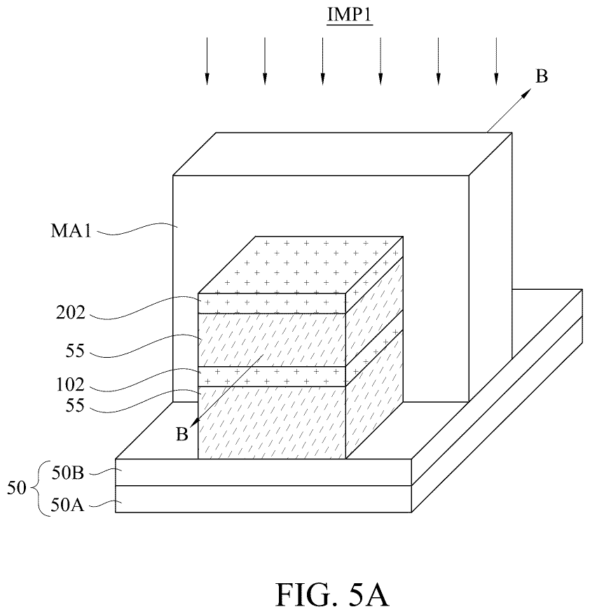

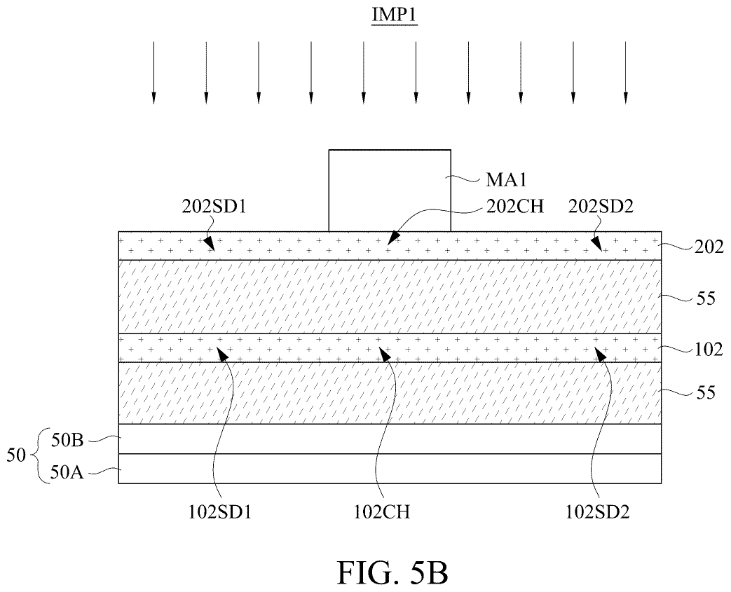

Reference is made to FIGS. 5A and 5B, in which FIG. 5A is a perspective view of a semiconductor device, FIG. 5B is a cross-sectional view along line B-B of FIG. 5A. An implantation process IMP1 is performed to dope the source/drain regions 102SD1 and 102SD2 of the first semiconductor layer 102. In some embodiments, the implants of the implantation process IMP1 may be n-type dopants, such as phosphorus (P), arsenic (As), or antimony (Sb), or the like. That is, after the first implantation process IMP1 is complete, the source/drain regions 110SD of the semiconductor layer 110 and the source/drain regions 120SD of the semiconductor layer 120 are both n-type doped regions. In some embodiments, the energy of the first implantation process IMP1 may be controlled such that the implants of the implantation process IMP1 are driven, passing through the second semiconductor layer 202, down to the first semiconductor layer 102. Accordingly, the second semiconductor layer 202 may not be doped during the implantation process IMP1. However, in other embodiments, the second semiconductor layer 202 may also be slightly doped, and thus n-type dopants may be detected in the source/drain regions 202SD1 and 202SD2 of the first semiconductor layer 202.

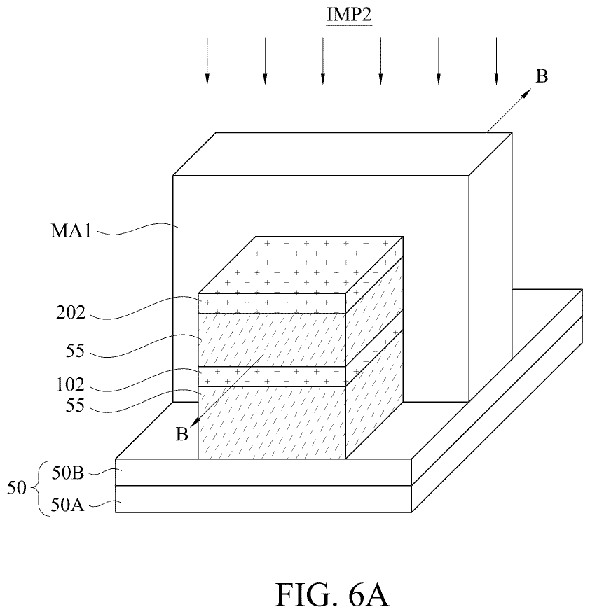

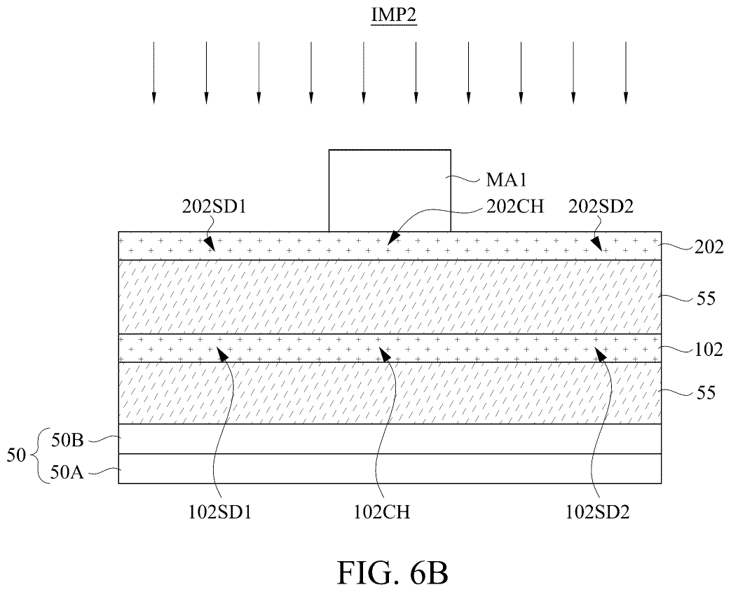

Reference is made to FIGS. 6A and 6B, in which FIG. 6A is a perspective view of a semiconductor device, FIG. 6B is a cross-sectional view along line B-B of FIG. 6A. An implantation process IMP2 is performed to dope the source/drain regions 202SD1 and 202SD2 of the first semiconductor layer 202. In some embodiments, the implants of the second implantation process IMP2 may be p-type dopants, such as boron (B), gallium (Ga), indium (In), aluminium (Al), or the like. That is, after the implantation process IMP2 is complete, source/drain regions 202SD1 and 202SD2 of the first semiconductor layer 202 are both p-type doped regions. In some embodiments, the energy of the implantation process IMP2 may be controlled such that the implants of the implantation process IMP2 are driven into the source/drain regions 202SD1 and 202SD2 of the second semiconductor layer 202. As mentioned above, the source/drain regions 202SD1 and 202SD2 of the second semiconductor layer 202 may be slightly doped during the implantation process IMP1, and thus both n-type dopants and p-type dopants may be detected in the source/drain regions 202SD1 and 202SD2 of the second semiconductor layer 202, while the dopant concentration of the p-type dopants is higher than the dopant concentration of the n-type dopants. Accordingly, the source/drain regions 202SD1 and 202SD2 of the second semiconductor layer 202 may present p-type conductivity.

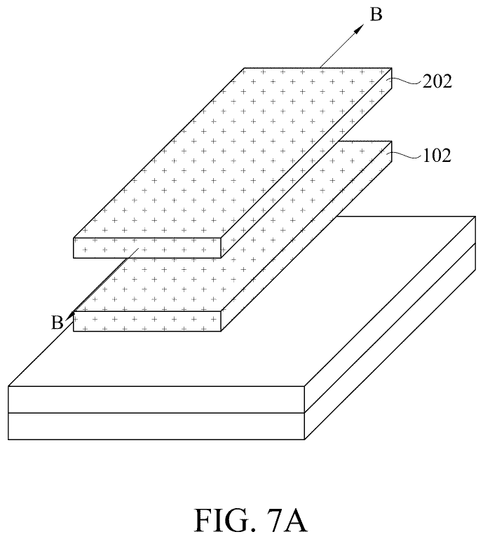

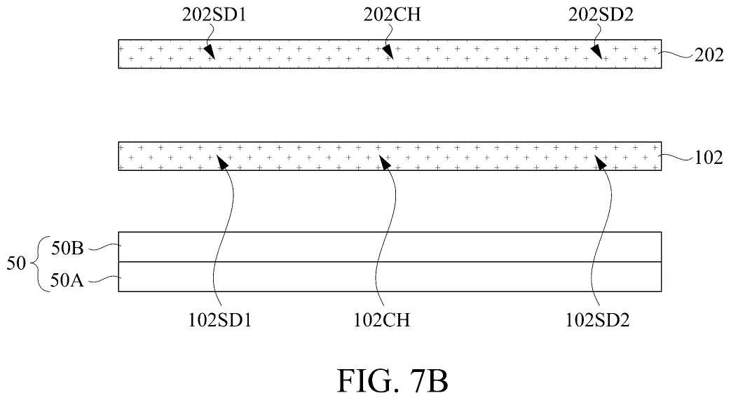

Reference is made to FIGS. 7A and 7B, in which FIG. 7A is a perspective view of a semiconductor device, FIG. 7B is a cross-sectional view along line B-B of FIG. 7A. The patterned mask is removed. Afterwards, the sacrificial layers 55 are removed, such that the first semiconductor layer 102 and the second semiconductor layer 202 are suspended over the substrate 50. In some embodiments, a patterned mask (not shown) may be formed over the substrate 50 and having an opening exposing unwanted portions of the sacrificial layers 55, and an etching process is then performed to remove the sacrificial layers 55 through the opening of the patterned mask. The suspended portions of the first semiconductor layer 102 and the second semiconductor layer 202 may be supported by other portions of the structure covered by the patterned mask (e.g., other portions of the structure where sacrificial layers 55 are not removed).

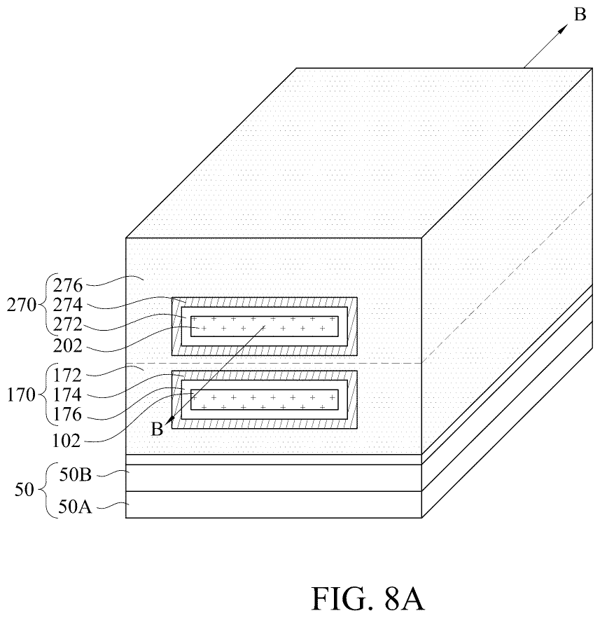

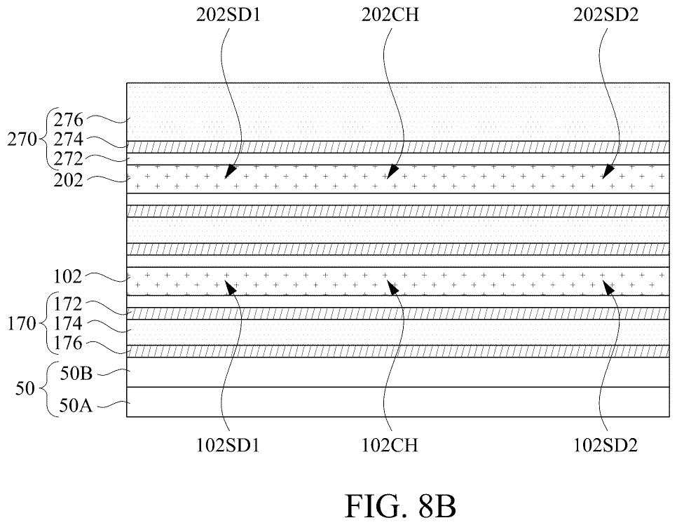

Reference is made to FIGS. 8A and 8B, in which FIG. 8A is a perspective view of a semiconductor device, FIG. 8B is a cross-sectional view along line B-B of FIG. 8A. A first metal gate structure 170 is formed over the substrate 50 and wrapping around the channel region 102CH of the first semiconductor layer 102, and a second metal gate structure 270 is formed over the first metal gate structure 170 and wrapping around the channel region 202CH of the second semiconductor layer 202.

The first metal gate structure 170 and the second metal gate structure 270 may be formed by, for example, performing an oxidation process to form the interfacial layer 172 and 272 selectively on the exposed surfaces of the first semiconductor layer 102 and the second semiconductor layer 202, respectively. Afterwards, a deposition process is performed to form the ferroelectric layers 174 and 274 over the interfacial layers 172 and 272, respectively. In some embodiments, the deposition process of forming the ferroelectric layers 174 and 274 may be suitable deposition technique, such as CVD, PECVD, metal oxide chemical vapor deposition (MOCVD), ALD, RPALD, PEALD, MBD or the like. In some embodiments, a material of the ferroelectric layers 174 and 274 is in contact with a top surface of the insulating layer 50B of the substrate 50. After the ferroelectric layers 174 and 274 are formed, a deposition process is performed to form the gate electrodes 176 and 276 over the ferroelectric layers 174 and 274, respectively. In some embodiments, the deposition process may include physical vapor deposition (PVD), chemical vapor deposition (CVD), atomic layer deposition (ALD), or the like.

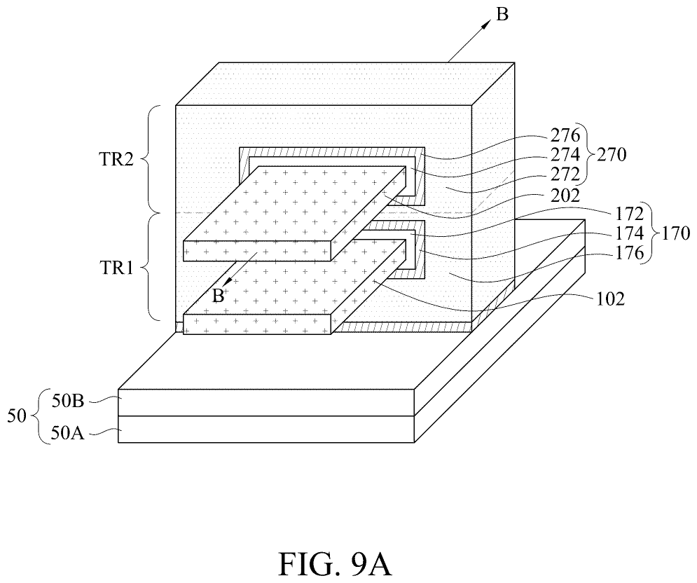

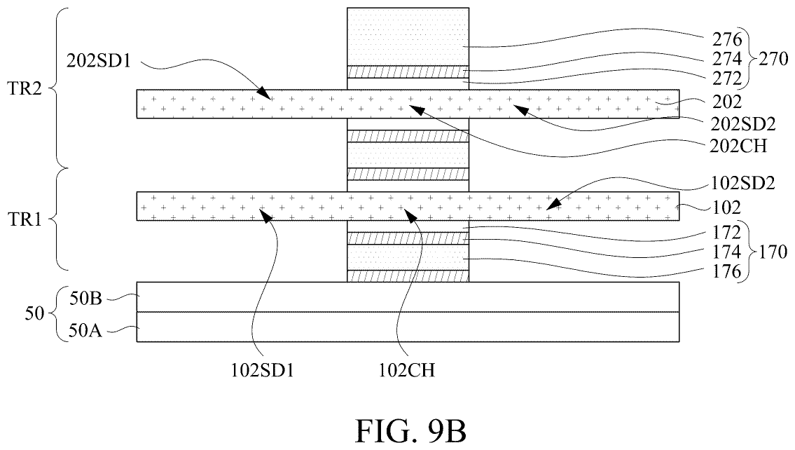

Reference is made to FIGS. 9A and 9B, in which FIG. 9A is a perspective view of a semiconductor device, FIG. 9B is a cross-sectional view along line B-B of FIG. 9A. The first gate structure 170 and the second gate structure 270 are patterned, such that the first gate structure 170 and the second gate structure 270 wrap around the channel region 102CH of the first semiconductor layer 102 and the channel region 202CH of the second semiconductor layer 202, respectively. Afterwards, the source/drain regions 102SD1 and 102SD2 of the first semiconductor layer 102 and the source/drain regions 202SD1 and 202SD2 of the second semiconductor layer 202 are exposed through the first gate structure 170 and the second gate structure 270 after the patterning process.

After the first gate structure 170 and the second gate structure 270 are patterned, a crystallization process may be performed to crystallize the ferroelectric layers 174 and 274. In greater detail, the crystallization process may be an annealing process performed under a temperature of about 350° C. to about 700° C. In some embodiments, the ferroelectric layers 174 and 274 may include amorphous structure. The crystallization process may be performed such that the ferroelectric layers 174 and 274 include fully crystalline structure or a partially crystalline structure; that is, each of the ferroelectric layers 174 and 274 is formed in a mixed crystalline-amorphous state and having some degree of structural order.

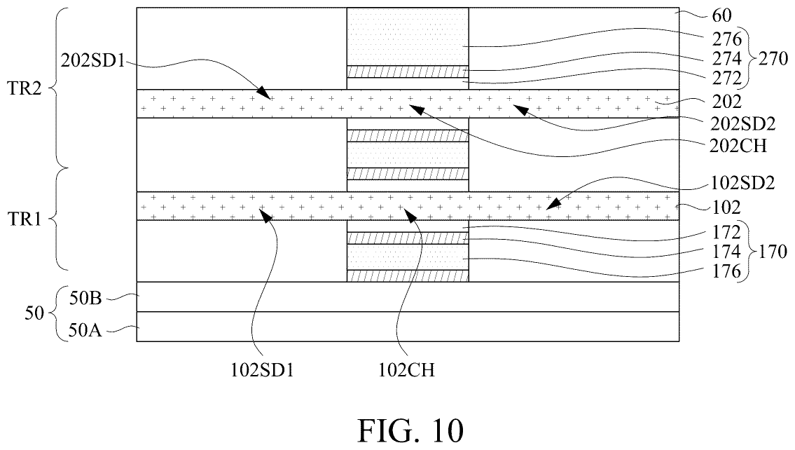

Reference is made to FIG. 10, in which FIG. 10 is a cross-sectional view following the cross-sectional view of FIG. 9B. A dielectric layer 60 is formed over the substrate 50 and covering the source/drain regions 102SD1 and 102SD2 of the first semiconductor layer 102 and the source/drain regions 202SD1 and 202SD2 of the second semiconductor layer 202. In some embodiments, the dielectric layer 60 may be formed by, for example, depositing a dielectric material over the substrate 50, and then performing a planarization process until the second gate structure 270 is exposed.

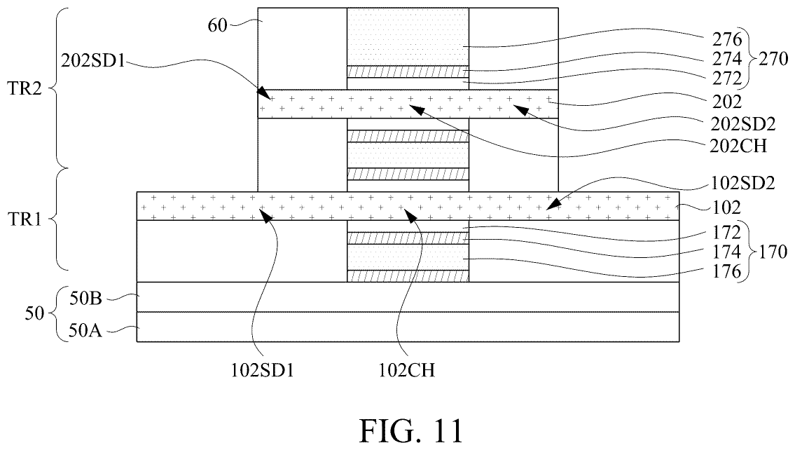

Reference is made to FIG. 11, in which FIG. 11 is a cross-sectional view following the cross-sectional view of FIG. 10. The dielectric layer 60 is patterned to expose portions of the source/drain regions 202SD1 and 202SD2 of the second semiconductor layer 202. Afterwards, an etching process is performed to remove the exposed portions of the source/drain regions 202SD1 and 202SD2 of the second semiconductor layer 202, so as to shorten the second semiconductor layer 202.

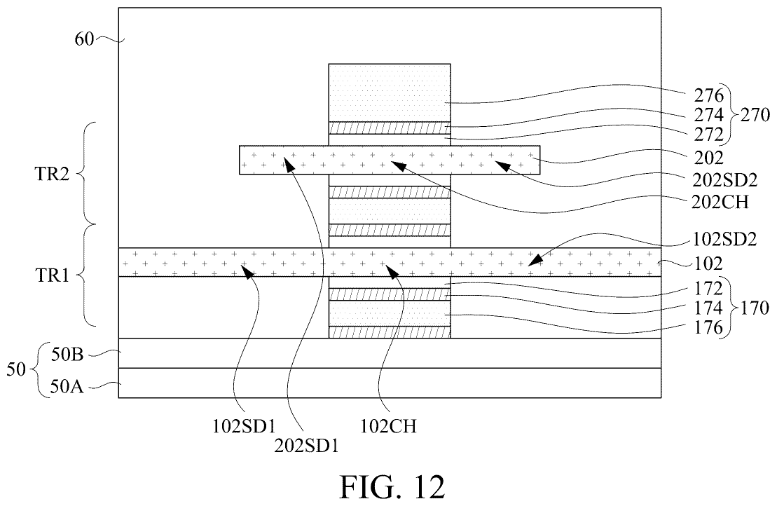

Reference is made to FIG. 12, in which FIG. 12 is a cross-sectional view following the cross-sectional view of FIG. 11. A dielectric material is deposited over the substrate 50 to rebuild the dielectric layer 60. Afterwards, the top surface of the dielectric layer 60 is higher than top surface of the second metal gate structure 270.

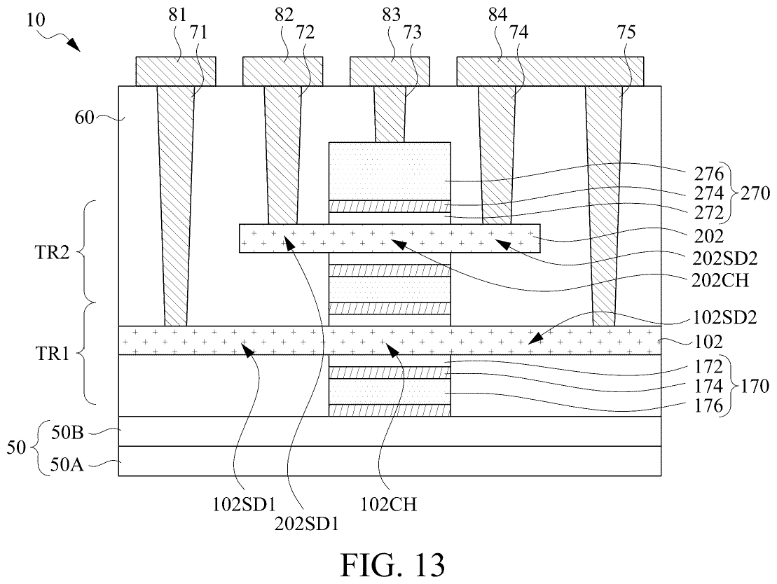

Reference is made to FIG. 13, in which FIG. 13 is a cross-sectional view following the cross-sectional view of FIG. 12. Conductive vias 71, 72, 73, 74, and 75 are formed in the dielectric layer 60. The conductive vias 71, 72, 73, 74, and 75 may be formed by, for example, forming a patterned mask (not shown) over the dielectric layer 60, in which the patterned mask may include several openings correspond to the positions of the conductive vias 71, 72, 73, 74, and 75. An etching process is performed to remove portions of the dielectric layer 60 through the openings of the patterned mask, so as to form openings in the dielectric layer 60. The patterned mask is then removed, and a conductive material is deposited in the openings of the dielectric layer 60. A planarization process, such as CMP, may be performed to remove excess conductive material outside the openings of the dielectric layer 60, and the portions of the conductive material remain in the openings may serve as the conductive vias 71, 72, 73, 74, and 75. Conductive pads 81, 82, 83, and 84 are formed over the dielectric layer 60. The conductive pads 81, 82, 83, and 84 may be formed by, for example, depositing a conductive layer over the dielectric layer 60, and then patterning the conductive layer according to a predetermined pattern.

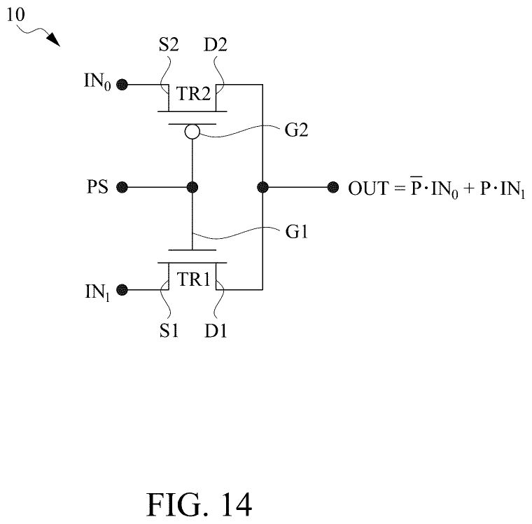

FIG. 14 is a circuit diagram of a semiconductor device in accordance with some embodiments of the present disclosure. FIG. 14 is similar to FIG. 1C, while in FIG. 14 the CFET 10 may function as a 2-to-1 multiplexer (2-to-1 MUX), and thus the CFET 10 is referred to as a 2-to-1 MUX 10 in the following discussion. Generally, a 2-to-1 MUX includes two inputs (e.g., input terminal IN₁ and input terminal IN₀), a selector (e.g., the polarization state terminal PS) and one output (e.g., output OUT). Depending on the select signal applied to the selector, the output is connected to either of the inputs. Since there are two input signals, only two ways are possible to connect the inputs to the outputs, so one select is needed to do these operations.

Prior to the operation, a write signal (e.g., a non-zero voltage) is firstly applied to the polarization state terminal PS to set the polarization states of the first transistor TR1 and the second transistor TR2. As mentioned above with respect to FIG. 1D, once the first transistor TR1 and the second transistor TR2 are polarized, the first transistor TR1 and the second transistor TR2 may include opposite polarization states. That is, when the first transistor TR1 has a polarization state P, the second transistor TR1 has a polarization state P̅. For example, when the first transistor TR1 has a polarization state “1”, the second transistor TR1 has a polarization state “0”. Alternatively, when the first transistor TR1 has a polarization state “0”, the second transistor TR1 has a polarization state “1”.

Accordingly, after setting the polarization states of the first transistor TR1 and the second transistor TR2, the 2-to-1 MUX 10 is operated by applying input signals to the input terminals IN₁ and IN₀, and the output signal is read at the output terminal OUT. In some embodiments, the output signal can be expressed as OUT=P̅·IN₀+P·IN₁. During operating the 2-to-1 MUX 10, a zero voltage (e.g., 0V) is applied to the polarization state terminal PS, such that a zero gate voltage (e.g., V_{G}=0) is applied to both the gate G1 of the first transistor TR1 and the gate G2 of the second transistor TR2.

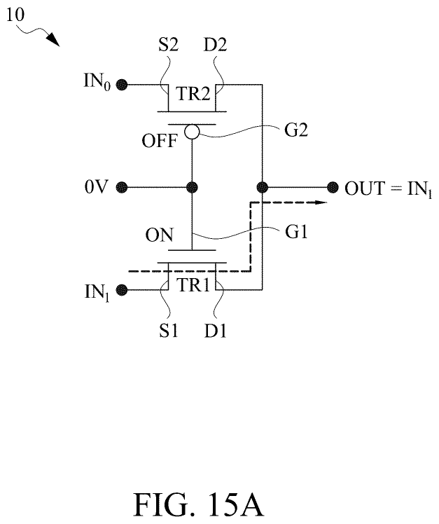

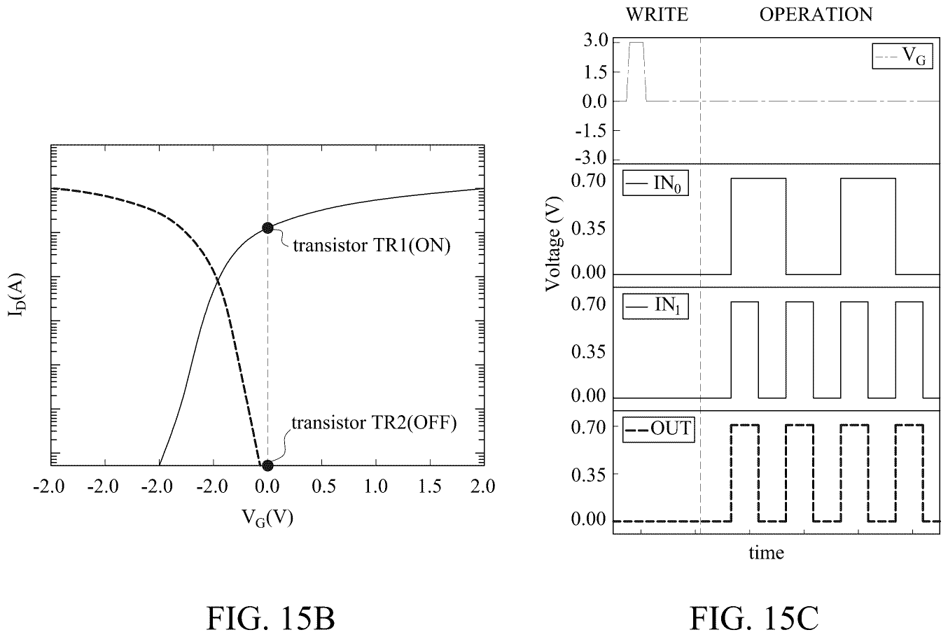

FIG. 15A is a circuit diagram of a semiconductor device in accordance with some embodiments of the present disclosure. FIGS. 15B and 15C are simulation results of a semiconductor device in accordance with some embodiments of the present disclosure. In greater detail, FIGS. 15A to 15C illustrate embodiments where the polarization states of the first transistor TR1 and the second transistor TR2 are “1” and “0”, respectively.

See FIGS. 15B and 15C, prior to the operation, a write signal is firstly applied to the polarization state terminal PS to set the polarization states of the first transistor TR1 and the second transistor TR2. In some embodiments, a positive write voltage is applied to the polarization state terminal PS. During applying the positive write voltage, the input terminals IN₁ and IN₀, and the output terminal OUT may be biased at ground voltage (e.g., 0V). The positive write voltage is applied to positively polarize the first transistor TR1 and the second transistor TR2, such that the first transistor TR1 and the second transistor TR2 are operated in depletion mode and enhancement mode at V_{G}=0, respectively. In some embodiments, the positive write voltage may be about 3.0V.

After the first transistor TR1 and the second transistor TR2 are positively polarized, an operation is performed to the 2-to-1 MUX 10. For example input signals are applied to the input terminals IN₁ and IN₀, respectively, and the output signal is read at the output terminal OUT. During the operation, the polarization state terminal PS is biased at 0V, such that that the gate voltages of the first transistor TR1 and the second transistor TR2 are both 0V (V_{G}=0). As shown in FIGS. 15A and 15B, when V_{G}=0, the first transistor TR1 has a low resistance (e.g., high drain current level) and the second transistor TR2 has a high resistance (e.g., low drain level or no drain current). That is, when V_{G}=0, the first transistor TR1 is turn ON, and the second transistor TR1 is turn OFF.

Accordingly, in FIG. 15A, current can only flow from the input terminal IN₁ through the first transistor TR1 (e.g., ON-state) to the output terminal OUT, while there is no current flow through the second transistor TR2 (e.g., OFF-state). That is, the output signal can be expressed as OUT=P̅·IN₀+P·IN₁=0·IN₀+1·IN₁=IN₁. It can also be seen in FIG. 15C, the input signal applied to the input terminal IN₁ can be read at the output terminal OUT.

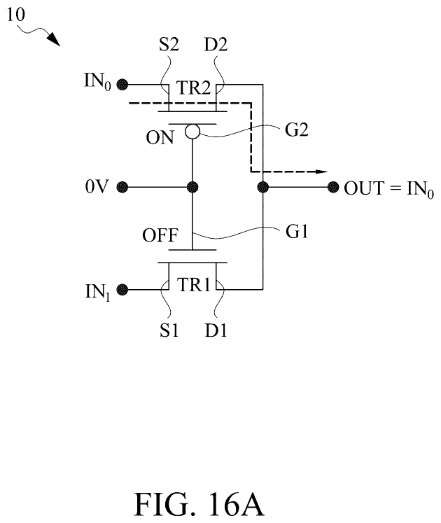

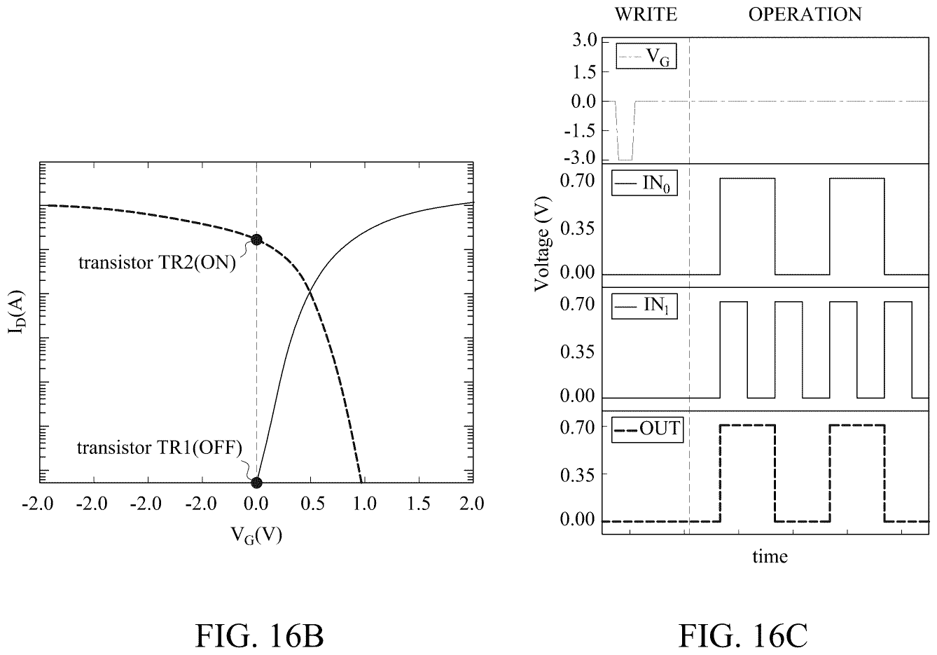

FIG. 16A is a circuit diagram of a semiconductor device in accordance with some embodiments of the present disclosure. FIGS. 16B and 16C are simulation results of a semiconductor device in accordance with some embodiments of the present disclosure. In greater detail, FIGS. 16A to 16C illustrate embodiments where the polarization states of the first transistor TR1 and the second transistor TR2 are “0” and “1”, respectively.

See FIGS. 16B and 16C, prior to the operation, a write signal is firstly applied to the polarization state terminal PS to set the polarization states of the first transistor TR1 and the second transistor TR2. In some embodiments, a negative write voltage is applied to the polarization state terminal PS. During applying the negative write voltage, the input terminals IN₁ and IN₀, and the output terminal OUT may be biased at ground voltage (e.g., 0V). The negative write voltage is applied to negatively polarize the first transistor TR1 and the second transistor TR2, such that the first transistor TR1 and the second transistor TR2 are operated in enhancement mode and depletion mode at V_{G}=0, respectively. In some embodiments, the negative write voltage may be about −3.0V.

After the first transistor TR1 and the second transistor TR2 are negatively polarized, an operation is performed to the 2-to-1 MUX 10. For example input signals are applied to the input terminals IN₁ and IN₀, respectively, and the output signal is read at the output terminal OUT. During the operation, the polarization state terminal PS is biased at 0V, such that that the gate voltages of the first transistor TR1 and the second transistor TR2 are both 0V (V_{G}=0). As shown in FIGS. 16A and 16B, when V_{G}=0, the first transistor TR1 has a high resistance (e.g., low drain level or no drain current), and the second transistor TR2 has a low resistance (e.g., high drain current level). That is, when V_{G}=0, the first transistor TR1 is turn OFF, and the second transistor TR1 is turn ON.

Accordingly, in FIG. 16A, current can only flow from the input terminal IN₀ through the second transistor TR2 (e.g., ON-state) to the output terminal OUT, while there is no current flow through the first transistor TR1 (e.g., OFF-state). That is, the output signal can be expressed as OUT=P̅·IN₀+P·IN₁=1·IN₀+0·IN₁=IN₁. It can also be seen in FIG. 16C, the input signal applied to the input terminal IN₀ can be read at the output terminal OUT.

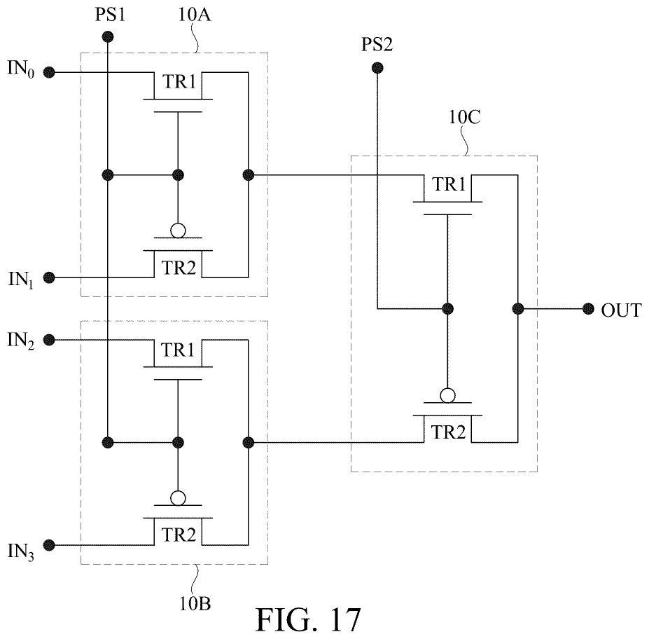

FIG. 17 is a circuit diagram of a semiconductor device in accordance with some embodiments of the present disclosure. In the circuit diagram of FIG. 17, there CFETs 10A, 10B, and 10C are electrically coupled with each other, in which each of the CFETs 10A, 10B, and 10C may include a same configuration as the CFET 10 as discussed above, and thus relevant details will not be repeated for brevity. In the circuit diagram of FIG. 17, the CFETs 10A, 10B, and 10C may function as a 2-to-1 MUX, and thus the CFETs 10A, 10B, and 10C may also be referred to as 2-to-1 MUXs 10A, 10B, and 10C in the following discussion.

In FIG. 17, the source of the second transistor TR2 of the CFET 10A is electrically coupled with an input terminal IN₀, and the source of the first transistor TR1 of the CFET 10A is electrically coupled with an input terminal IN₁. The source of the second transistor TR2 of the CFET 10B is electrically coupled with an input terminal IN₂, and the source of the first transistor TR1 of the CFET 10B is electrically coupled with an input terminal IN₃. The gates of the first transistor TR1 and the second transistor TR2 of the CFET 10A, and the gates of the first transistor TR1 and the second transistor TR2 of the CFET 10B are electrically coupled with a polarization state terminal PS1. Accordingly, the first transistor TR1 and the second transistor TR2 of the CFET 10A and the first transistor TR1 and the second transistor TR2 of the CFET 10B can be polarized simultaneously. The drain of the second transistor TR2 of the CFET 10A and the drain of the first transistor TR1 of the CFET 10A are electrically coupled with the source of the first transistor TR1 of the CFET 10C. On the other hand, the drain of the second transistor TR2 of the CFET 10B and the drain of the first transistor TR1 of the CFET 10B are electrically coupled with the source of the second transistor TR2 of the CFET 10C. The gates of the first transistor TR1 and the second transistor TR2 of the CFET 10C are electrically coupled with a polarization state terminal PS2. The drain of the first transistor TR1 of the CFET 10C and the drain of the second transistor TR2 of the CFET 10C are electrically coupled with an output terminal OUT.

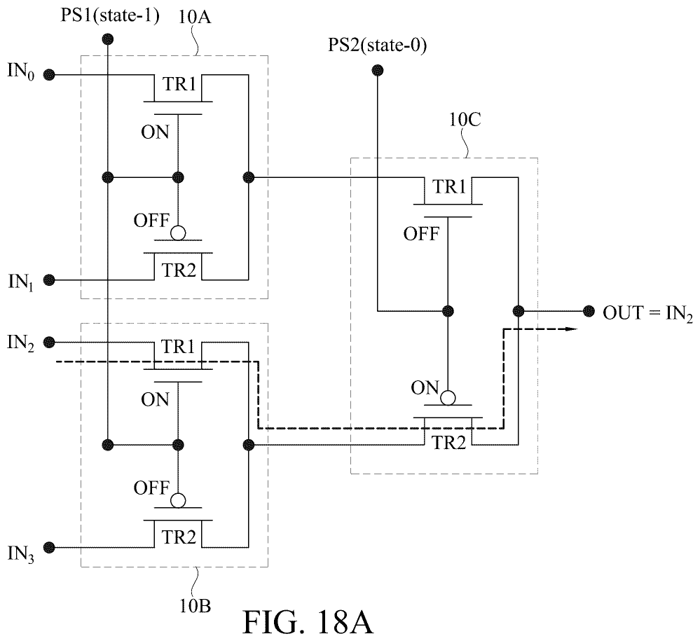

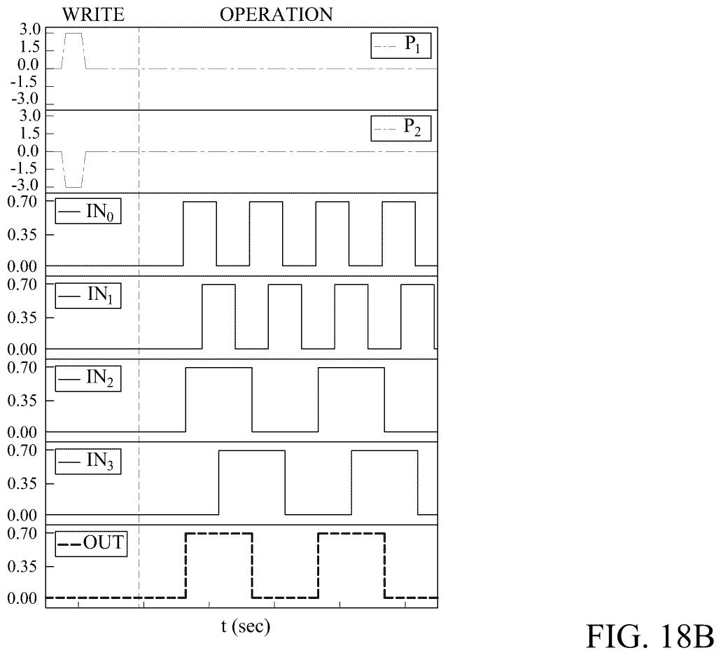

FIGS. 18A, 19A, 20A, and 21A are circuit diagrams of a semiconductor device at different polarization states in accordance with some embodiments of the present disclosure. FIGS. 18B, 19B, 20B, and 21B are simulation results a semiconductor device at different polarization states in accordance with some embodiments of the present disclosure.

Reference is made to FIGS. 18A and 18B. In the embodiments of FIGS. 18A and 18B, a positive write voltage (state-1) is applied to the polarization state terminal PS1, and a negative write voltage (state-0) is applied to the polarization state terminal PS2, so as to set the polarization states of the first transistors TR1 and the second transistors TR2 of the CFETs 10A, 10B, and 10C, respectively.

In response to the positive write voltage applied to the polarization state terminal PS1, the first transistors TR1 and the second transistors TR2 of the CFETs 10A and 10B are positively polarized. That is, when V_{G}=0, the first transistors TR1 of the CFETs 10A and 10B are turn ON, while the second transistors TR2 of the CFETs 10A and 10B are turn OFF. On the contrary, in response to the negative write voltage applied to the polarization state terminal PS2, the first transistors TR1 and the second transistors TR2 of the CFET 10C are negatively polarized. That is, when V_{G}=0, the first transistor TR1 of the CFET 10C is turn OFF, while the second transistor TR2 of the CFET 10C is turn ON. It is understood that during applying the write voltages to the polarization state terminals PS1 and PS2, the input terminals IN₀, IN₁, IN₂, and IN₃, and the output terminal OUT are biased at 0V.

Accordingly, during the operation, the polarization state terminals PS1 and PS2 are biased at 0V, and input signals are applied to the input terminals IN₀, IN₁, IN₂, and IN₃, respectively, and output signal is read at the output terminal OUT. As shown in FIG. 18A, current can only be allowed to flow from the input terminal IN₂, through the first transistor TR1 of the CFET 10B (e.g., ON-state) and the second transistor TR2 of the CFET 10C (e.g., ON-state), to the output terminal OUT. It can also be seen in FIG. 18B, the input signal applied to the input terminal IN₂ can be read at the output terminal OUT.

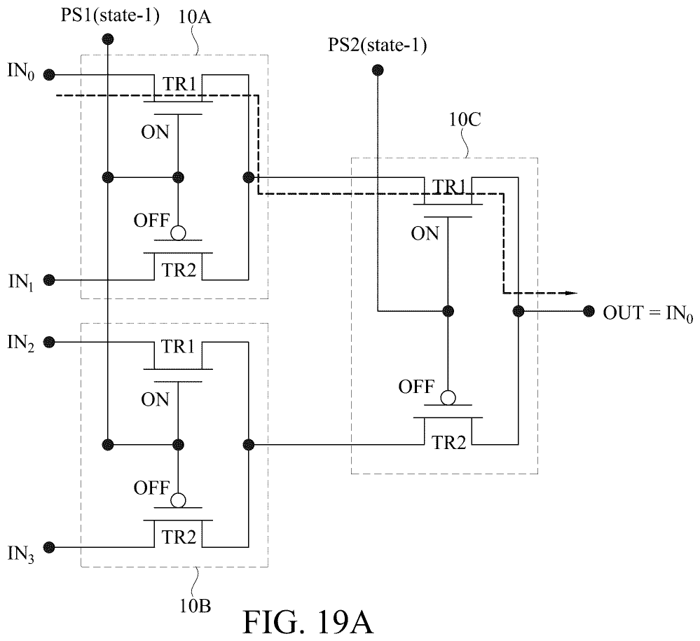

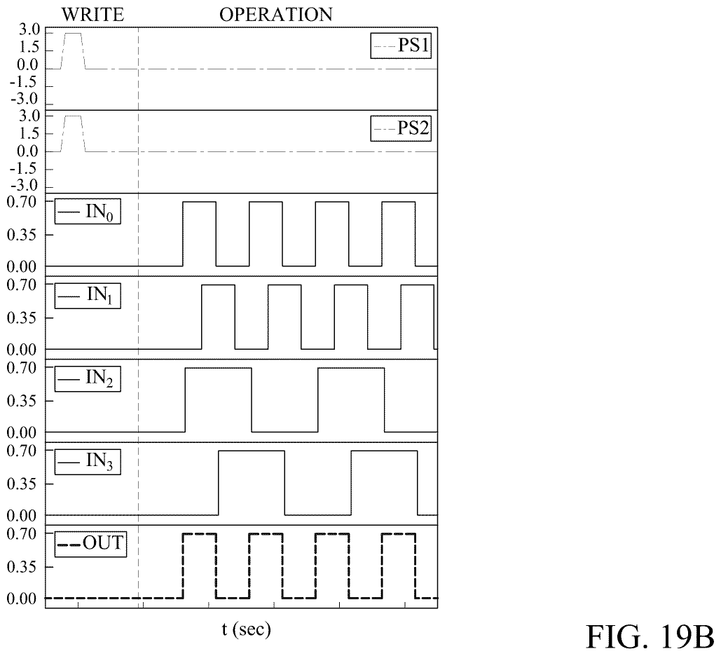

Reference is made to FIGS. 19A and 19B. In the embodiments of FIGS. 19A and 19B, a positive write voltage (state-1) is applied to the polarization state terminal PS1, and a positive write voltage (state-1) is applied to the polarization state terminal PS2, so as to set the polarization states of the first transistors TR1 and the second transistors TR2 of the CFETs 10A, 10B, and 10C, respectively.

In response to the positive write voltage applied to the polarization state terminal PS1, the first transistors TR1 and the second transistors TR2 of the CFETs 10A and 10B are positively polarized. That is, when V_{G}=0, the first transistors TR1 of the CFETs 10A and 10B are turn ON, while the second transistors TR2 of the CFETs 10A and 10B are turn OFF. Similarly, in response to the positive write voltage applied to the polarization state terminal PS2, the first transistors TR1 and the second transistors TR2 of the CFET 10C are positively polarized. That is, when V_{G}=0, the first transistor TR1 of the CFET 10C is turn ON, while the second transistor TR2 of the CFET 10C is turn OFF. It is understood that during applying the write voltages to the polarization state terminals PS1 and PS2, the input terminals IN₀, IN₁, IN₂, and IN₃, and the output terminal OUT are biased at 0V.

Accordingly, during the operation, the polarization state terminals PS1 and PS2 are biased at 0V, and input signals are applied to the input terminals IN₀, IN₁, IN₂, and IN₃, respectively, and output signal is read at the output terminal OUT. As shown in FIG. 19A, current can only be allowed to flow from the input terminal IN₀, through the first transistor TR1 of the CFET 10A (e.g., ON-state) and the first transistor TR1 of the CFET 10C (e.g., ON-state), to the output terminal OUT. It can also be seen in FIG. 19B, the input signal applied to the input terminal IN₀ can be read at the output terminal OUT.

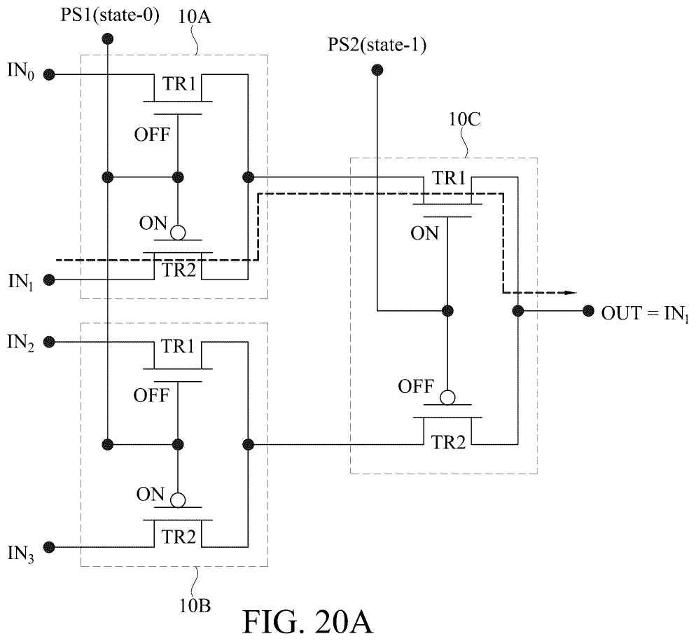

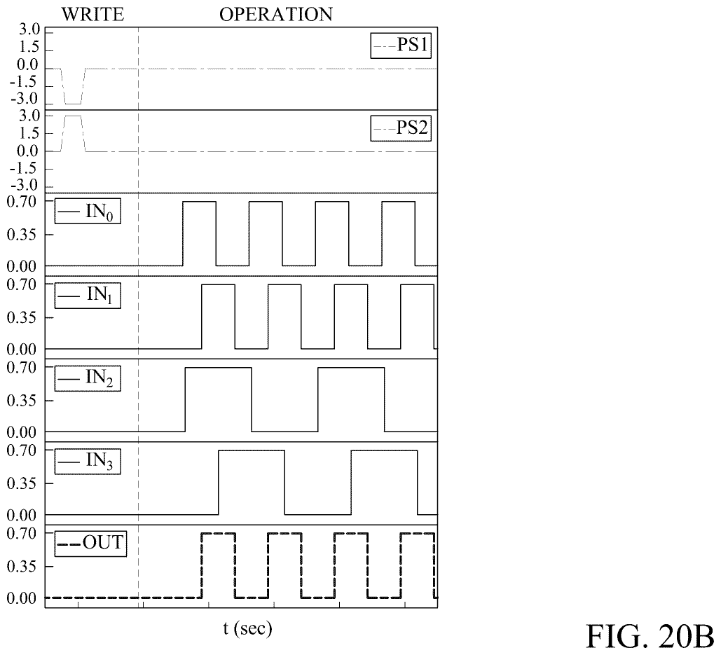

Reference is made to FIGS. 20A and 20B. In the embodiments of FIGS. 20A and 20B, a negative write voltage (state-0) is applied to the polarization state terminal PS1, and a positive write voltage (state-1) is applied to the polarization state terminal PS2, so as to set the polarization states of the first transistors TR1 and the second transistors TR2 of the CFETs 10A, 10B, and 10C, respectively.

In response to the negative write voltage applied to the polarization state terminal PS1, the first transistors TR1 and the second transistors TR2 of the CFETs 10A and 10B are negatively polarized. That is, when V_{G}=0, the first transistors TR1 of the CFETs 10A and 10B are turn OFF, while the second transistors TR2 of the CFETs 10A and 10B are turn ON. On the contrary, in response to the positive write voltage applied to the polarization state terminal PS2, the first transistors TR1 and the second transistors TR2 of the CFET 10C are positively polarized. That is, when V_{G}=0, the first transistor TR1 of the CFET 10C is turn ON, while the second transistor TR2 of the CFET 10C is turn OFF. It is understood that during applying the write voltages to the polarization state terminals PS1 and PS2, the input terminals IN₀, IN₁, IN₂, and IN₃, and the output terminal OUT are biased at 0V.

Accordingly, during the operation, the polarization state terminals PS1 and PS2 are biased at 0V, and input signals are applied to the input terminals IN₀, IN₁, IN₂, and IN₃, respectively, and output signal is read at the output terminal OUT. As shown in FIG. 20A, current can only be allowed to flow from the input terminal IN₁, through the second transistor TR2 of the CFET 10A (e.g., ON-state) and the first transistor TR1 of the CFET 10C (e.g., ON-state), to the output terminal OUT. It can also be seen in FIG. 20B, the input signal applied to the input terminal IN₁ can be read at the output terminal OUT.

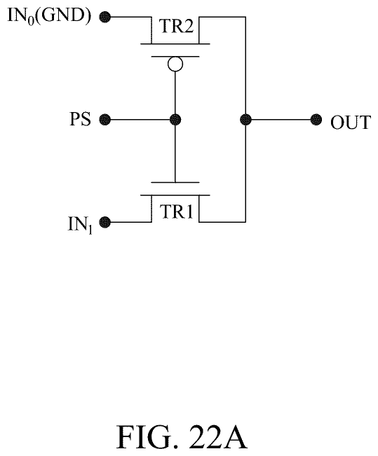

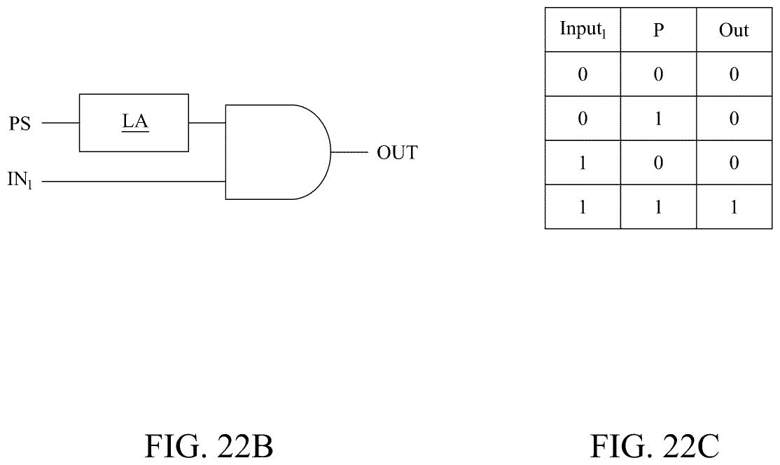

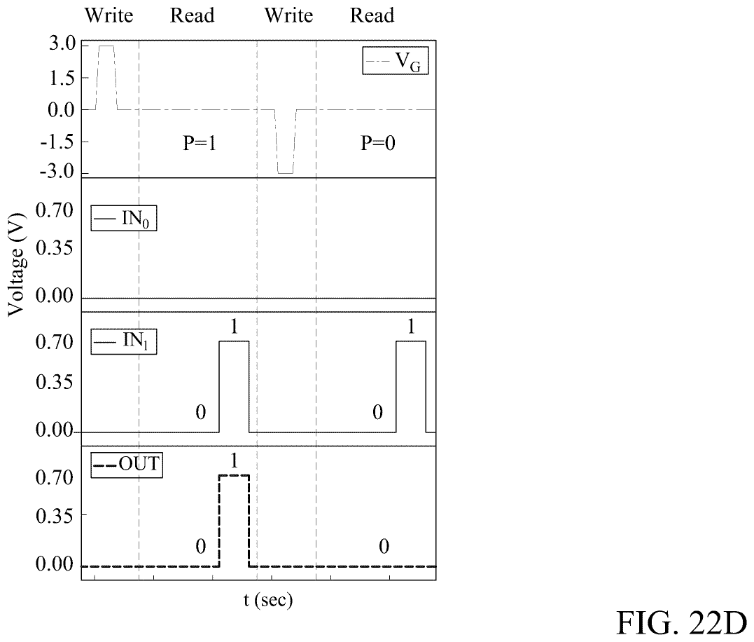

Reference is made to FIGS. 22A and 22B. In the embodiments of FIGS. 20A and 20B, a negative write voltage (state-0) is applied to the polarization state terminal PS1, and a negative write voltage (state-0) is applied to the polarization state terminal PS2, so as to set the polarization states of the first transistors TR1 and the second transistors TR2 of the CFETs 10A, 10B, and 10C, respectively.

In response to the negative write voltage applied to the polarization state terminal PS1, the first transistors TR1 and the second transistors TR2 of the CFETs 10A and 10B are negatively polarized. That is, when V_{G}=0, the first transistors TR1 of the CFETs 10A and 10B are turn OFF, while the second transistors TR2 of the CFETs 10A and 10B are turn ON. Similarly, in response to the negative write voltage applied to the polarization state terminal PS2, the first transistors TR1 and the second transistors TR2 of the CFET 10C are negatively polarized. That is, when V_{G}=0, the first transistor TR1 of the CFET 10C is turn OFF, while the second transistor TR2 of the CFET 10C is turn ON. It is understood that during applying the write voltages to the polarization state terminals PS1 and PS2, the input terminals IN₀, IN₁, IN₂, and IN₃, and the output terminal OUT are biased at 0V.

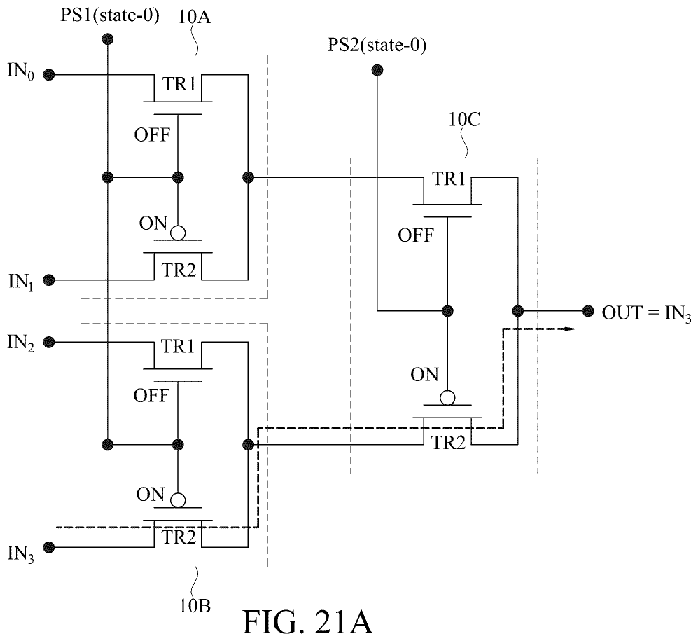

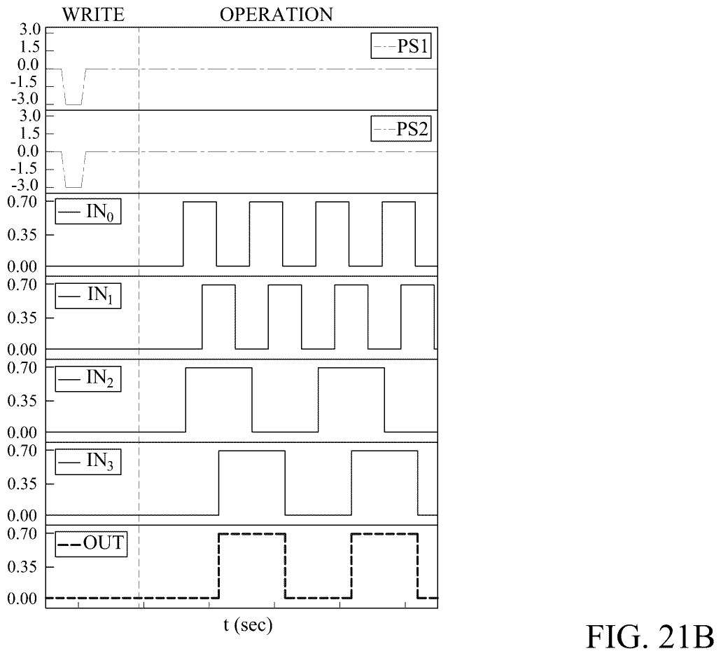

Accordingly, during the operation, the polarization state terminals PS1 and PS2 are biased at 0V, and input signals are applied to the input terminals IN₀, IN₁, IN₂, and IN₃, respectively, and output signal is read at the output terminal OUT. As shown in FIG. 21A, current can only be allowed to flow from the input terminal IN₃, through the second transistor TR2 of the CFET 10A (e.g., ON-state) and the second transistor TR2 of the CFET 10C (e.g., ON-state), to the output terminal OUT. It can also be seen in FIG. 21B, the input signal applied to the input terminal IN₃ can be read at the output terminal OUT.

FIGS. 22A, 22B, 22C, and 22D are a circuit diagram, an equivalent circuit, a true table, and a simulation result of a semiconductor device, respectively, in accordance with some embodiments of the present disclosure. In greater detail, when the input terminal IN₀ is grounded (e.g., biased at 0V), an AND logic function may present between the polarization state terminal PS and the input terminal IN₁. Accordingly, the CFET 10 can also be referred to as AND gate 10 in the following discussion.

To operate the AND gate 10, a write operation is firstly performed by applying a polarization signal to the polarization state terminal PS to polarize the first transistor TR1 and the second transistor TR2 of the AND gate 10. During the write operation, the input terminal IN₁ is biased at 0V. After the write operation is complete, a read operation is performed by applying an input signal to the input terminal IN₁, and the output signal is read at the output terminal OUT. During the read operation, the polarization state terminal PS is biased at 0V.

For example, during the write operation, if a positive voltage (logic level “1”) is applied to the polarization state terminal PS, the first transistor TR1 and the second transistor TR2 of the AND gate 10 are positively polarized. That is, when V_{G}=0, the first transistors TR1 is turn ON, while the second transistors TR2 is turn OFF. Accordingly, during the read operation, current can only flow from the input terminal IN₁ through the first transistor TR1 (e.g., ON-state) to the output terminal OUT. Therefore, when a positive voltage (logic level “1”) is applied to the input terminal IN₁, a positive voltage (logic level “1”) can be read at the output terminal OUT. When a zero voltage (logic level “0”) is applied to the input terminal IN₁, a zero voltage (logic level “0”) can be read at the output terminal OUT.

On the other hand, if a negative voltage (logic level “0”) is applied to the polarization state terminal PS, the first transistor TR1 and the second transistor TR2 of the AND gate 10 are negatively polarized. That is, when V_{G}=0, the first transistors TR1 is turn OFF, while the second transistors TR2 is turn ON. Accordingly, during the read operation, current can only flow from the input terminal IN₀ through the second transistor TR2 (e.g., ON-state) to the output terminal OUT. However, the input terminal IN₀ is grounded, and thus only voltage (logic level “0”) can be read at the output terminal OUT regardless the input signal applied to the input terminal IN₁.

FIG. 22B illustrates an equivalent circuit of the AND gate structure, in which the AND gate has the polarization state terminal PS and the input terminal IN₁ as the inputs, and the output terminal OUT as the output. The polarization state terminal PS is connected with a latch element LA. In some embodiments, the latch element LA may be first transistor TR1 and the second transistor TR2, which allows to store a previous data during the write operation, and can serve as an input of the AND gate.

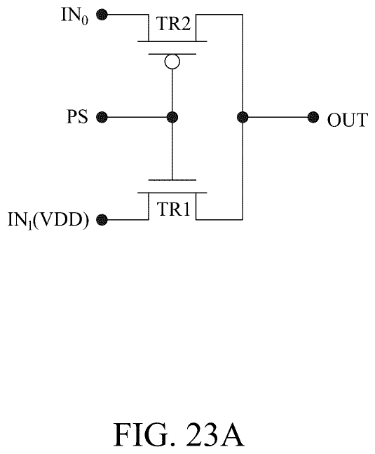

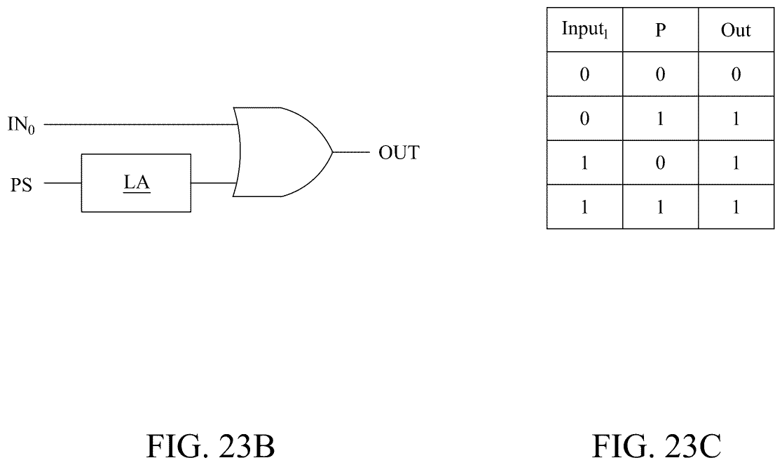

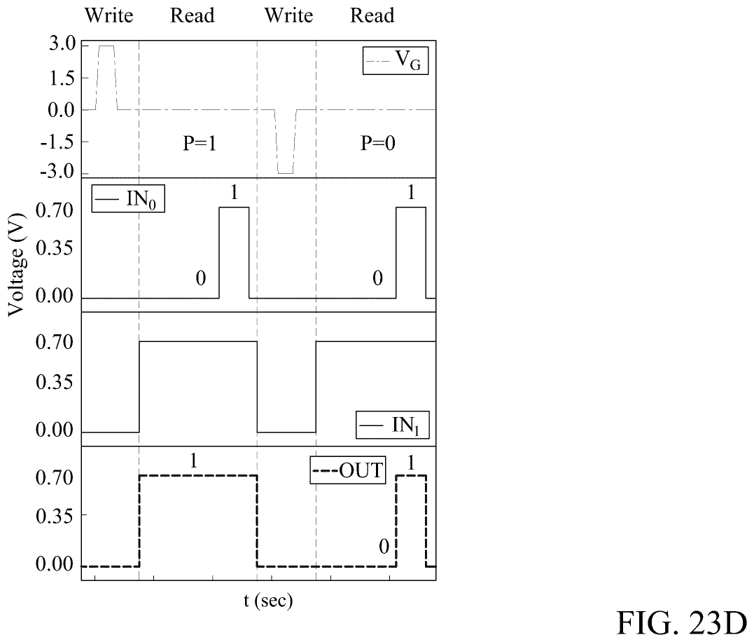

FIGS. 23A, 23B, 23C, and 23D are a circuit diagram, an equivalent circuit, a true table, and a simulation result of a semiconductor device, respectively, in accordance with some embodiments of the present disclosure. In greater detail, when the input terminal IN₁ is biased at a high voltage level during a read operation, an OR logic function may present between the polarization state terminal PS and the input terminal IN₀. Accordingly, the CFET 10 can also be referred to as OR gate 10 in the following discussion.

To operate the OR gate 10, a write operation is firstly performed by applying a polarization signal to the polarization state terminal PS to polarize the first transistor TR1 and the second transistor TR2 of the OR gate 10. During the write operation, the input terminals IN₀ and IN₁ are biased at 0V. After the write operation is complete, a read operation is performed by applying an input signal to the input terminal IN₀, and the output signal is read at the output terminal OUT. During the read operation, the polarization state terminal PS is biased at 0V, and the input terminal IN₁ is biased at a high voltage level. Here, the “high voltage level” may be a positive voltage level greater than 0V, and is substantially equal to the logic level “1” recognized by the output terminal OUT.

For example, during the write operation, if a positive voltage (logic level “1”) is applied to the polarization state terminal PS, the first transistor TR1 and the second transistor TR2 of the OR gate 10 are positively polarized. That is, when V_{G}=0, the first transistors TR1 is turn ON, while the second transistors TR2 is turn OFF. Accordingly, during the read operation, current can only flow from the input terminal IN₁ through the first transistor TR1 (e.g., ON-state) to the output terminal OUT. However, the input terminal IN₁ is biased at a constant high voltage level (logic level “1”), and thus only high voltage level (logic level “1”) can be read at the output terminal OUT regardless the input signal applied to the input terminal IN₀.

On the other hand, if a negative voltage (logic level “0”) is applied to the polarization state terminal PS, the first transistor TR1 and the second transistor TR2 of the AND gate 10 are negatively polarized. That is, when V_{G}=0, the first transistors TR1 is turn OFF, while the second transistors TR2 is turn ON. Accordingly, during the read operation, current can only flow from the input terminal IN₀ through the second transistor TR2 (e.g., ON-state) to the output terminal OUT. Therefore, when a positive voltage (logic level “1”) is applied to the input terminal IN₀, a positive voltage (logic level “1”) can be read at the output terminal OUT. When a zero voltage (logic level “0”) is applied to the input terminal IN₀, a zero voltage (logic level “0”) can be read at the output terminal OUT.

FIG. 23B illustrates an equivalent circuit of the OR gate structure, in which the OR gate has the polarization state terminal PS and the input terminal IN₀ as the inputs, and the output terminal OUT as the output. The polarization state terminal PS is connected with a latch element LA. In some embodiments, the latch element LA may be first transistor TR1 and the second transistor TR2, which allows to store a previous data during the write operation, and can serve as an input of the OR gate.

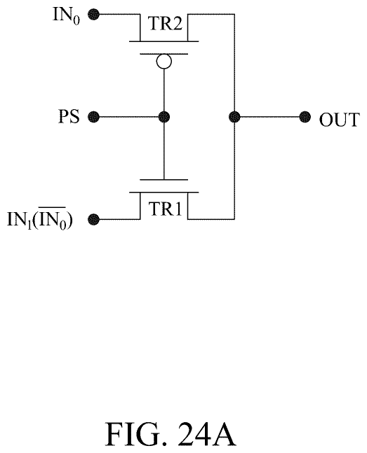

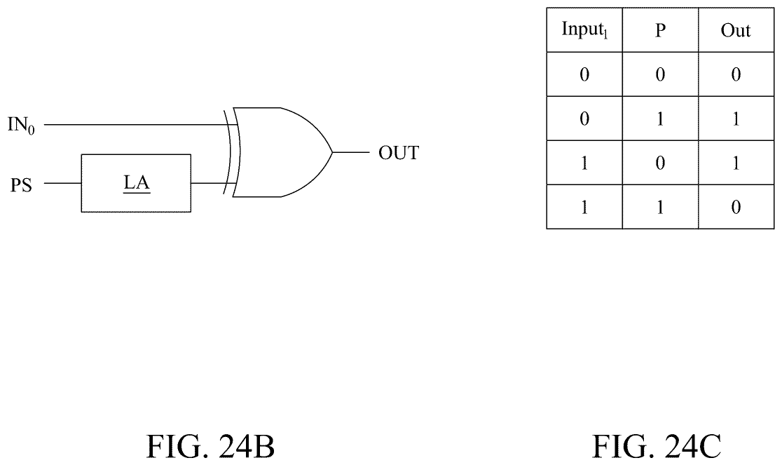

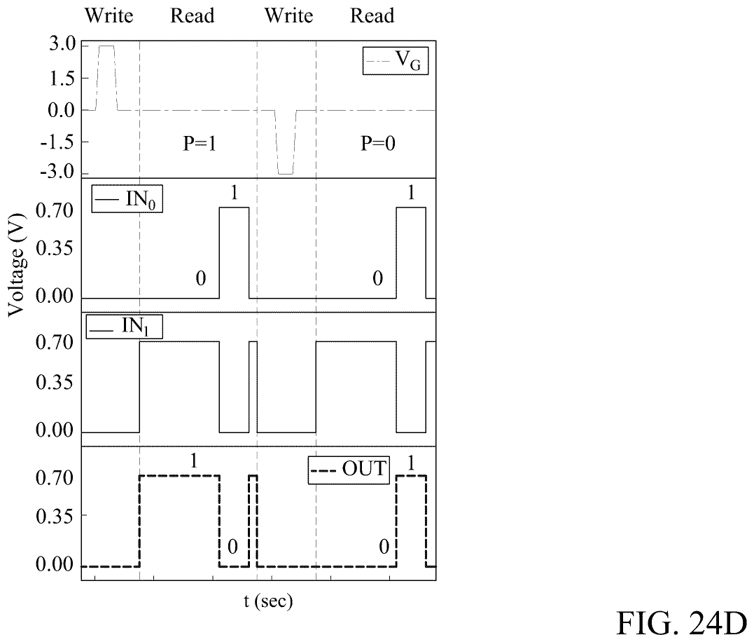

FIGS. 24A, 24B, 24C, and 24D are a circuit diagram, an equivalent circuit, a true table, and a simulation result of a semiconductor device, respectively, in accordance with some embodiments of the present disclosure. In greater detail, when the input terminal IN₀ and input terminal IN₁ are biased with complementary signal during the read operation, an XOR logic function may present between the polarization state terminal PS and the input terminal IN₀. That is, during the read operation, the terminal IN₀ and input terminal IN₁ are biased with opposite logic levels (e.g., IN₁=I̅N̅₀̅). Accordingly, the CFET 10 can also be referred to as XOR gate 10 in the following discussion.

For example, during the write operation, if a positive voltage (logic level “1”) is applied to the polarization state terminal PS, the first transistor TR1 and the second transistor TR2 of the OR gate 10 are positively polarized. That is, when VG =0, the first transistors TR1 is turn ON, while the second transistors TR2 is turn OFF. Accordingly, during the read operation, current can only flow from the input terminal IN₁ through the first transistor TR1 (e.g., ON-state) to the output terminal OUT. Therefore, when a positive voltage (logic level “1”) is applied to the input terminal IN₀, a zero voltage (logic level “0”) is therefore applied to the input terminal IN₁. Accordingly, a zero voltage (logic level “0”) can be read at the output terminal OUT. When a zero voltage (logic level “0”) is applied to the input terminal IN₀, a positive voltage (logic level “1”) is therefore applied to the input terminal IN₁. Accordingly, a positive voltage (logic level “1”) can be read at the output terminal OUT.

On the other hand, if a negative voltage (logic level “0”) is applied to the polarization state terminal PS, the first transistor TR1 and the second transistor TR2 of the AND gate 10 are negatively polarized. That is, when V_{G}=0, the first transistors TR1 is turn OFF, while the second transistors TR2 is turn ON. Accordingly, during the read operation, current can only flow from the input terminal IN₀ through the second transistor TR2 (e.g., ON-state) to the output terminal OUT. Therefore, when a positive voltage (logic level “1”) is applied to the input terminal IN₀, a zero voltage (logic level “0”) is therefore applied to the input terminal IN₁. Accordingly, a positive voltage (logic level “1”) can be read at the output terminal OUT. When a zero voltage (logic level “0”) is applied to the input terminal IN₀, a positive voltage (logic level “1”) is therefore applied to the input terminal IN₁. Accordingly, zero voltage (logic level “0”) can be read at the output terminal OUT.

FIG. 24B illustrates an equivalent circuit of the XOR gate structure, in which the OR gate has the polarization state terminal PS and the input terminal IN₀ as the inputs, and the output terminal OUT as the output. The polarization state terminal PS is connected with a latch element LA. In some embodiments, the latch element LA may be first transistor TR1 and the second transistor TR2, which allows to store a previous data during the write operation, and can serve as an input of the XOR gate.

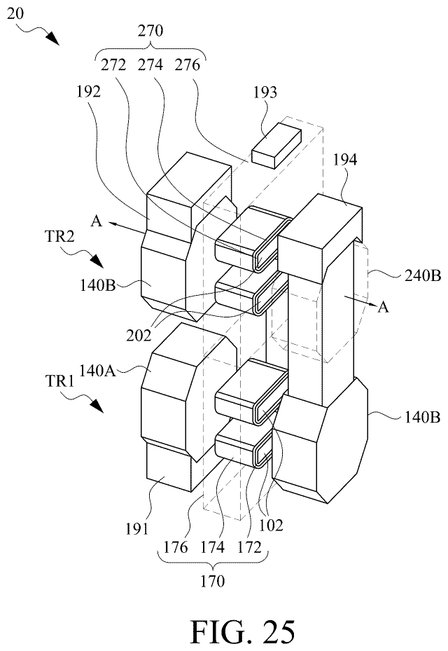

FIG. 25 is a perspective view of a semiconductor device in accordance with some embodiments of the present disclosure. It is noted that some elements of FIG. 25 have been described above with respect to FIGS. 1A and 1B, such elements are labeled the same, and relevant details will not be repeated for brevity. A complementary FET (CFET) 20 is provided, and its manufacturing method will be disclosed in the following discussion. More specifically, the CFET 10 is a complementary ferroelectric FET (CFeFET), which includes ferroelectric transistors stacked on above another, which will be discussed in the following content.

The CFET 20 includes a first transistor TR1, and a second transistor TR2 is vertically above the first transistor TR1. With respect to the first transistor TR1, the first transistor TR1 includes first semiconductor layers 102, a first metal gate structure 170 wrapping around the first semiconductor layers 102, and source/drain epitaxy structures 140A and 140B on opposite sides of the first semiconductor layer 102. Similarly, the second transistor TR2 includes second semiconductor layers 202, a second metal gate structure 270 wrapping around the second semiconductor layers 202, and source/drain epitaxy structures 240A and 240B on opposite sides of the second semiconductor layer 202. In some embodiments, the gate electrodes 176 and 276 are made of different materials.

The CFET 20 further includes a source/drain contact 191 in contact with a bottom surface of the source/drain epitaxy structure 140A, a source/drain contact 192 in contact with a top surface of the source/drain epitaxy structure 240A, a gate via 193 in contact with a top surface of the second metal gate structure 270, and a source/drain contact 194 penetrating through the source/drain epitaxy structure 240B and in contact with a top surface of the source/drain epitaxy structure 140B.

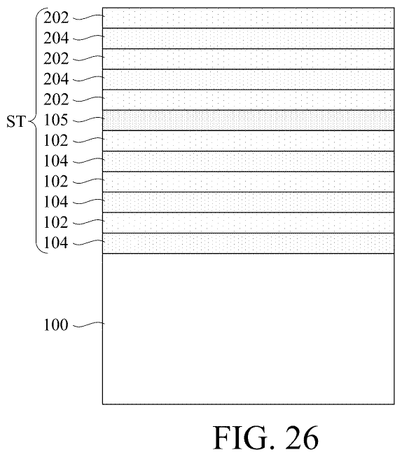

FIGS. 26 to 31 illustrate a method in various stages of forming a semiconductor device in accordance with some embodiments of the present disclosure. In greater detail, FIGS. 26 to 31 illustrate a method for forming the CFET 20 of FIG. 25, in which FIGS. 26 to 31 are cross-sectional view along line A-A of FIG. 25. Although FIGS. 26 to 31 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 26 to 31 may be similar to those described above, and thus relevant details will not be repeated for brevity.

Reference is made to FIG. 26. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack of alternating semiconductor layers 102 and 104, a semiconductor layer 105 disposed over the first stack, and a second stack of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 60 percent and about 80 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers.

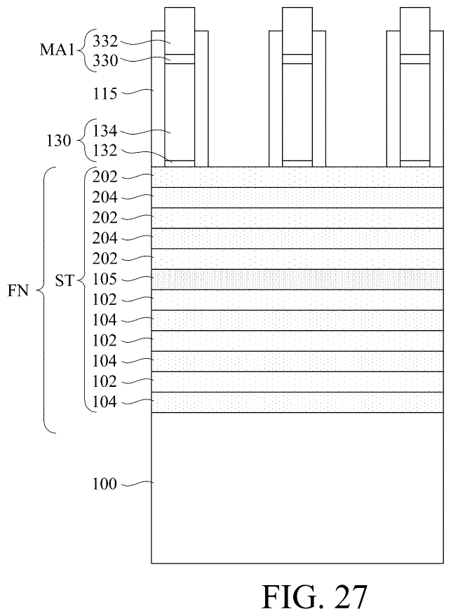

Reference is made to FIG. 27. Dummy gate structures 130 are formed over the substrate 100 and crossing the stack ST. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Gate spacers 115 are formed on opposite sidewalls of each of the dummy gate structures 130. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130. In some embodiments, the remaining vertical portions of the spacer layer can be referred to as the gate spacers 115. The spacer layer may be deposited using techniques such CVD, ALD, or the like.

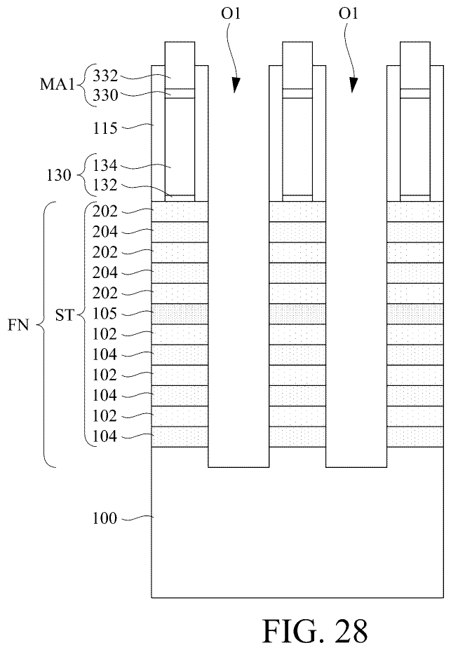

Reference is made to FIG. 28. An etching process is performed to remove portions of the stack ST by using the dummy gate structures 130 and the gate spacers 115 as etch mask, so as to form source/drain openings O1 in the stack ST. In some embodiments, the etching process may be wet etch, dry etch, or combinations thereof. In some embodiments, the bottommost ends of the source/drain openings O1 may be lower than the bottommost semiconductor layer 104.

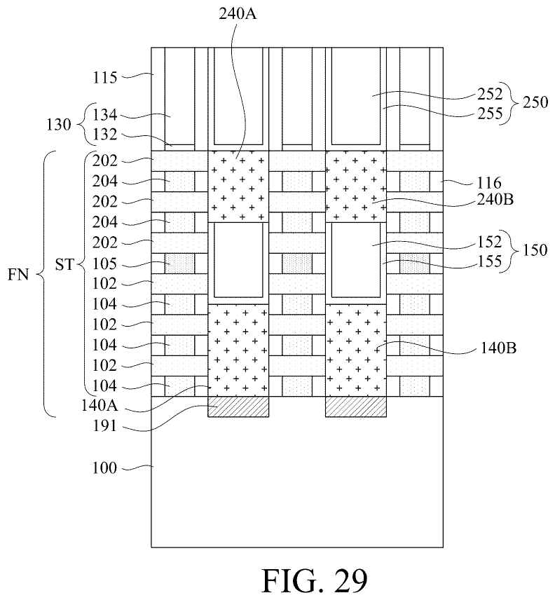

Reference is made to FIG. 29. The semiconductor layers 104 and the semiconductor layers 204 are laterally etched to form sidewall recesses. Afterwards, inner spacers 116 are formed in the sidewall recesses on opposite ends of each of the semiconductor layers 104, the semiconductor layers 204.

Source/drain contacts 191 are formed in the bottom portions of the source/drain openings O1. In some embodiments, the source/drain contacts 191 may be formed by, for example, depositing a conductive material in the source/drain openings O1, and then etching back the conductive material to a desired position.

Source/drain epitaxy structures 140A and 140B are formed in the openings O1 and on opposite ends of each semiconductor layer 102, respectively. The source/drain epitaxy structures 140A and 140B may be formed by suitable deposition process, such as a selective epitaxial growth (SEG) process. In some embodiments, an implantation process may be performed to the source/drain epitaxy structures 140A and 140B. For example, the implantation process may include n-type dopants.

A contact etch stop layer (CESL) 155 is formed covering the first source/drain epitaxy structures 140, and an interlayer dielectric (ILD) layer 152 is formed over the CESL 155. Then, an etching back process is performed to lower top surfaces of the CESL 155 and the ILD layer 152, such that sidewalls of the semiconductor layers 202 are exposed through the source/drain openings O1. In some embodiments, the CESL 155 and the ILD layer 152 can be collectively referred to as an isolation structure 150. In some embodiments, the topmost semiconductor layer 102 and the bottommost semiconductor layer 202 are in contact with the CESL 155 of the isolation structure 150.

In some embodiments, the CESL 155 may be nitride (such as silicon nitride), and the ILD layer 152 may be oxide (such as silicon oxide). In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

Source/drain epitaxy structures 240A and 240B are formed on opposite ends of each of the semiconductor layers 202. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the semiconductor layers 202. In some embodiments, an implantation process may be performed to the second source/drain epitaxy structures 240. For example, the implantation process may include p-type dopants.

A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 130 are exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively. For example, the CESL 255 may be nitride (such as silicon nitride), and the ILD layer 252 may be oxide (such as silicon oxide).

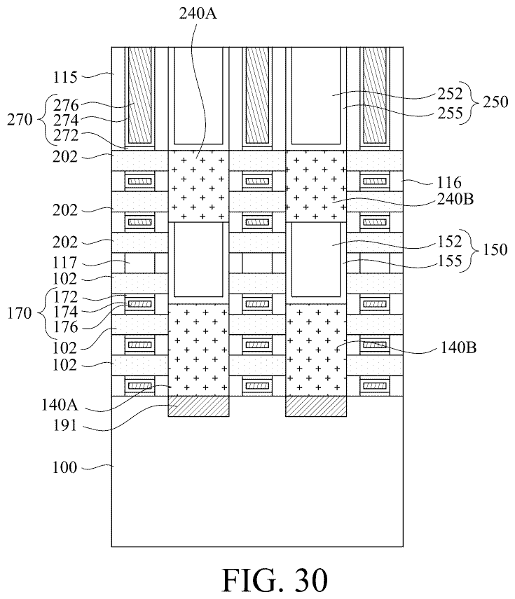

Reference is made to FIG. 30. The dummy gate structures 130 are removed to form gate trenches between each pair of the gate spacers 115. Then, an etching process is performed to remove the semiconductor layers 104 and 204 through the gate trenches, such that that the semiconductor layers 102 and the semiconductor layers 202 are suspended over the substrate 100. Then, the semiconductor layers 105 are replaced with isolation layers 117.

Interfacial layers 172 and 272 are formed on exposed surfaces of the semiconductor layers 102 and 202, respectively. Then, ferroelectric layers 174 and 274 are formed over the interfacial layers 172 and 272, respectively. In some embodiments, the interfacial layers 172 and 272 may be formed using a same deposition process, and the ferroelectric layers 174 and 274 may be formed using a same deposition process.

After the interfacial layers 172 and 272 and the ferroelectric layers 174 and 274 are formed, gate electrodes 176 are formed in the gate trenches and over the ferroelectric layers 174. The gate electrodes 176 are then etched back. Accordingly, first metal gate structures 170 are formed. Gate electrodes 276 are then formed in the gate trenches and over the first metal gate structures 170. Accordingly, second metal gate structures 270 are formed. In some embodiments, the gate electrodes 176 and 276 are made of different materials.

After the first gate structure 170 and the second gate structure 270 are formed, a crystallization process may be performed to crystallize the ferroelectric layers 174 and 274. In greater detail, the crystallization process may be an annealing process performed under a temperature of about 350° C. to about 700° C. In some embodiments, the ferroelectric layers 174 and 274 may include amorphous structure. The crystallization process may be performed such that the ferroelectric layers 174 and 274 include fully crystalline structure or a partially crystalline structure; that is, each of the ferroelectric layers 174 and 274 is formed in a mixed crystalline-amorphous state and having some degree of structural order.

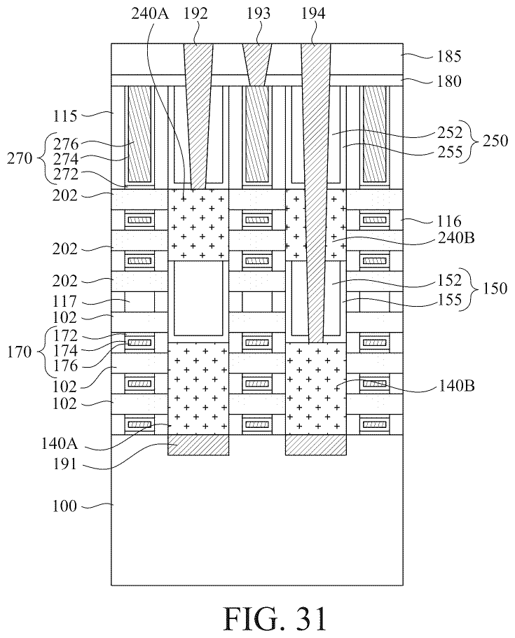

Reference is made to FIG. 31. An etch stop layer (ESL) 180 is formed over the isolation structures 250 and the second metal gate structures 270. Afterwards, an interlayer dielectric (ILD) layer 185 is formed over the ESL 180. The materials of the ESL 180 and the ILD layer 185 may be similar to the materials of the CESL 155 and the ILD layer 152, respectively. For example, the ESL 180 may be nitride (such as silicon nitride), and the ILD layer 185 may be oxide (such as silicon oxide). The ESL 180 and the ILD layer 185 can be formed using, for example, CVD, ALD or other suitable techniques.

Source/drain contact 192, gate via 193, and source/drain contact 194 are then formed. In greater detail, the source/drain contact 192 is formed in the ESL 180, the ILD layer 185, and the isolation structure 250 and in contact with a top surface of the source/drain epitaxy structure 240A. The gate via 193 is formed in the ESL 180, the ILD layer 185, and in contact with a top surface of the second metal gate structure 270. The the source/drain contact 192 is formed penetrating through the ESL 180, the ILD layer 185, the isolation structure 250, the source/drain epitaxy structure 240B, the isolation structure 150, and in contact with a top surface of the source/drain epitaxy structure 140B.

It is noted that the circuit diagram of the structure of the CFET 20 of FIG. 31 is the same as the circuit diagram of FIG. 1C. With respect to FIG. 31 and FIG. 1C, the gate G1, the source S1, and the drain D1 of the first transistor TR1 may be the first metal gate structure 170, the source/drain epitaxy structure 140A, and the source/drain epitaxy structure 140B, respectively. Similarly, the gate G2, the source S2, and the drain D2 of the second transistor TR2 may be the second metal gate structure 270, the source/drain epitaxy structure 240A, and the source/drain epitaxy structure 240B, respectively. The source/drain contact 191, the source/drain contact 192, the gate via 193, and the source/drain contact 194 of FIG. 31 may serve as the input terminal IN1, the input terminal IN0, the polarization state terminal PS, and the output terminal OUT of FIG. 1C, respectively.

It is understood that the CFET 20 as discussed with respect to FIGS. 25 to 31 can also have various applications as discussed above. For example, the CFET 10 (or CFETs 10A, 10B, and 10C in FIG. 17) discussed above can be replaced with the CFET 20. In particular, the CFET 20 may function as a 2-to-1 MUX, an AND gate, an OR gate, and/or a XOR gate as discussed above, while relevant details are not repeated for brevity.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a CFET having a first transistor and a second transistor vertically above the first transistor. The first transistor and the second transistor may be ferroelectric transistor and may include opposite conductivity types. This allows both the first and second ferroelectric transistor can be switched back and forth between a first state (enhancement mode) and a second state (depletion mode). Embodiments of the present disclosure also provide various applications of the CFET, such as 2-to-1 multiplexer. Moreover, based on the 2-to-1 multiplexer configuration, the CFET can also be utilized to realize reconfigurable AND/OR/XOR logic gates.

In some embodiments of the present disclosure, a method includes forming a first semiconductor layer and a second semiconductor layer vertically above the first semiconductor layer over a substrate; forming a first ferroelectric layer and a second ferroelectric layer wrapping around the first semiconductor layer and the second semiconductor layer, respectively; forming a first gate electrode and a second gate electrode over the first ferroelectric layer and the second ferroelectric layer, respectively, wherein the first gate electrode is in contact with the second gate electrode; and forming a conductive feature electrically connecting a drain region of the first semiconductor layer with a drain region of the second semiconductor layer.

In some embodiments, the first gate electrode and the second gate electrode are made of a same material.

In some embodiments, the method further includes etching back the first gate electrode prior to forming the second gate electrode, wherein the first gate electrode and the second gate electrode are made of different materials.

In some embodiments, the method further includes performing an annealing process to crystallize the first ferroelectric layer and the second ferroelectric layer.

In some embodiments, forming the first ferroelectric layer and the second ferroelectric layer further comprises forming a material of the first ferroelectric layer and the second ferroelectric layer along a top surface of the substrate.

In some embodiments, the method further includes prior to forming the first ferroelectric layer and the second ferroelectric layer, forming a first interfacial layer and a second interfacial layer wrapping around the first semiconductor layer and the second semiconductor layer, respectively.

In some embodiments, the method further includes forming a dummy gate structure over the first semiconductor layer and the second semiconductor layer; and removing the dummy gate structure prior to forming the forming the first gate electrode and a second gate electrode.

In some embodiments, the method further includes performing a first implantation process to dope n-type dopants in a source region and the drain region of the first semiconductor layer; and performing a second implantation process to dope p-type dopants in a source region and the drain region of the second semiconductor layer.

In some embodiments of the present disclosure, a method includes receiving a structure comprising a first ferroelectric transistor and a second ferroelectric transistor vertically above the first ferroelectric transistor; applying a write voltage to a gate of the first ferroelectric transistor and a gate of the second ferroelectric transistor to set polarization states of the first ferroelectric transistor and the second ferroelectric transistor; and after applying the write voltage, applying a zero voltage to the gate of the first ferroelectric transistor and the gate of the second ferroelectric transistor, such that one of the first and second ferroelectric transistors presents a high drain current level and another one of the first and second ferroelectric transistors presents a low drain current level, the low drain current level being less than the high drain current level.

In some embodiments, the method further includes during applying the zero voltage to the gate of the first ferroelectric transistor and the gate of the second ferroelectric transistor, applying a first input signal and a second input signal to a source region of the first ferroelectric transistor and a source region of the second ferroelectric transistor, respectively; and after applying the first input signal and the second input signal, reading an output signal from a terminal connecting with a drain region of the first ferroelectric transistor and a drain region of the second ferroelectric transistor.

In some embodiments, the write voltage is a positive voltage, such that the first ferroelectric transistor presents the high drain current level and the second ferroelectric transistor presents the low drain current level during applying the first input signal and the second input signal and reading the output signal, and the output signal is the same as the first input signal.

In some embodiments, the write voltage is a negative voltage, such that the first ferroelectric transistor presents the low drain current level and the second ferroelectric transistor presents the high drain current level during applying the first input signal and the second input signal and reading the output signal, and the output signal is the same as the second input signal.

In some embodiments, during applying the write voltage, a source region of the first ferroelectric transistor and a source region of the second ferroelectric transistor are biased with zero voltage.

In some embodiments, the first ferroelectric transistor and the second ferroelectric transistor have opposite conductivity types.

In some embodiments, wherein the gate of the first ferroelectric transistor and the gate of the second ferroelectric transistor each includes an interfacial layer, a ferroelectric layer over the interfacial layer, and a gate electrode layer over the ferroelectric layer.

In some embodiments of the present disclosure, a semiconductor device includes a first transistor over a substrate, including a first semiconductor channel layer, a first gate structure wrapping around the first semiconductor channel layer and including a first ferroelectric layer, and a first source region and a first drain region on opposite sides of the first semiconductor channel layer. A second transistor is over the substrate and includes a second semiconductor channel layer, a second gate structure wrapping around the second semiconductor channel layer and comprising a second ferroelectric layer, and a second source region and a second drain region on opposite sides of the second semiconductor channel layer. An output terminal is electrically connected with the first drain region of the first transistor and the second drain region of the second transistor.

In some embodiments, the second transistor is vertically above the first transistor, and the first transistor and the second transistor are n-type transistor and p-type transistor, respectively.

In some embodiments, the first gate structure and the second gate structure are made of same material.

In some embodiments, the semiconductor device further includes a first input terminal electrically connected with the first source region of the first transistor, and a second input terminal electrically connected with the second source region of the second transistor, wherein the first input terminal and the second input terminal are spaced apart from each other.

In some embodiments, the semiconductor device further includes a material of the first ferroelectric layer in contact with a top surface of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor layer and a second semiconductor layer vertically above the first semiconductor layer over a substrate;
forming a first ferroelectric layer and a second ferroelectric layer wrapping around the first semiconductor layer and the second semiconductor layer, respectively;
forming a first gate electrode and a second gate electrode over the first ferroelectric layer and the second ferroelectric layer, respectively, wherein the first gate electrode is in contact with the second gate electrode; and
forming a conductive feature electrically connecting a drain region of the first semiconductor layer with a drain region of the second semiconductor layer.

2. The method of claim 1, wherein the first gate electrode and the second gate electrode are made of a same material.

3. The method of claim 1, further comprising etching back the first gate electrode prior to forming the second gate electrode, wherein the first gate electrode and the second gate electrode are made of different materials.

4. The method of claim 1, further comprising performing an annealing process to crystallize the first ferroelectric layer and the second ferroelectric layer.

5. The method of claim 1, wherein forming the first ferroelectric layer and the second ferroelectric layer further comprises forming a material of the first ferroelectric layer and the second ferroelectric layer along a top surface of the substrate.

6. The method of claim 5, further comprising, prior to forming the first ferroelectric layer and the second ferroelectric layer, forming a first interfacial layer and a second interfacial layer wrapping around the first semiconductor layer and the second semiconductor layer, respectively.

7. The method of claim 1, further comprising:
forming a dummy gate structure over the first semiconductor layer and the second semiconductor layer; and
removing the dummy gate structure prior to forming the forming the first gate electrode and a second gate electrode.

8. The method of claim 1, further comprising:
performing a first implantation process to dope n-type dopants in a source region and the drain region of the first semiconductor layer; and
performing a second implantation process to dope p-type dopants in a source region and the drain region of the second semiconductor layer.

9. A method, comprising:
receiving a structure comprising a first ferroelectric transistor and a second ferroelectric transistor vertically above the first ferroelectric transistor;
applying a write voltage to a gate of the first ferroelectric transistor and a gate of the second ferroelectric transistor to set polarization states of the first ferroelectric transistor and the second ferroelectric transistor; and
after applying the write voltage, applying a zero voltage to the gate of the first ferroelectric transistor and the gate of the second ferroelectric transistor, such that one of the first and second ferroelectric transistors presents a high drain current level and another one of the first and second ferroelectric transistors presents a low drain current level, the low drain current level being less than the high drain current level.

10. The method of claim 9, further comprises:
during applying the zero voltage to the gate of the first ferroelectric transistor and the gate of the second ferroelectric transistor, applying a first input signal and a second input signal to a source region of the first ferroelectric transistor and a source region of the second ferroelectric transistor, respectively; and
after applying the first input signal and the second input signal, reading an output signal from a terminal connecting with a drain region of the first ferroelectric transistor and a drain region of the second ferroelectric transistor.

11. The method of claim 10, wherein the write voltage is a positive voltage, such that the first ferroelectric transistor presents the high drain current level and the second ferroelectric transistor presents the low drain current level during applying the first input signal and the second input signal and reading the output signal, and the output signal is the same as the first input signal.

12. The method of claim 10, wherein the write voltage is a negative voltage, such that the first ferroelectric transistor presents the low drain current level and the second ferroelectric transistor presents the high drain current level during applying the first input signal and the second input signal and reading the output signal, and the output signal is the same as the second input signal.

13. The method of claim 10, wherein during applying the write voltage, a source region of the first ferroelectric transistor and a source region of the second ferroelectric transistor are biased with zero voltage.

14. The method of claim 9, wherein the first ferroelectric transistor and the second ferroelectric transistor have opposite conductivity types.

15. The method of claim 9, wherein the gate of the first ferroelectric transistor and the gate of the second ferroelectric transistor each comprises:
an interfacial layer;
a ferroelectric layer over the interfacial layer; and
a gate electrode layer over the ferroelectric layer.

16. A semiconductor device, comprising:
a first transistor over a substrate, comprising:
a first semiconductor channel layer;
a first gate structure wrapping around the first semiconductor channel layer and comprising a first ferroelectric layer; and
a first source region and a first drain region on opposite sides of the first semiconductor channel layer;
a second transistor over the substrate, comprising:
a second semiconductor channel layer;
a second gate structure wrapping around the second semiconductor channel layer and comprising a second ferroelectric layer; and
a second source region and a second drain region on opposite sides of the second semiconductor channel layer; and
an output terminal electrically connected with the first drain region of the first transistor and the second drain region of the second transistor.

17. The semiconductor device of claim 16, wherein the second transistor is vertically above the first transistor, and the first transistor and the second transistor are n-type transistor and p-type transistor, respectively.

18. The semiconductor device of claim 16, wherein the first gate structure and the second gate structure are made of same material.

19. The semiconductor device of claim 16, further comprising:
a first input terminal electrically connected with the first source region of the first transistor; and
a second input terminal electrically connected with the second source region of the second transistor, wherein the first input terminal and the second input terminal are spaced apart from each other.

20. The semiconductor device of claim 16, further comprising a material of the first ferroelectric layer in contact with a top surface of the substrate.
